(19) United States
(12) Patent Application Publication
(10) Pub. No.: US 2026/0369225 A1
(43) Pub. Date: Nov. 19, 2026

(54) DISPLAY PANEL AND DISPLAY APPARATUS

(71) Applicant: Xiamen Tianma Display Technology Co., Ltd., Xiamen (CN)

(72) Inventors: Huomei HUA, Xiamen (CN); Huangyao WU, Xiamen (CN)

(21) Appl. No.: 19/426,526

(22) Filed: Dec. 19, 2025

(30) Foreign Application Priority Data
May 13, 2025 (CN) 202510612235.4

(51) Int. Cl. G09G 3/3233; H10K 59/131

(52) U.S. Cl. CPC G09G 3/3233; H10K 59/131; G09G 2300/0426; G09G 2300/0452; G09G 2300/0819; G09G 2300/0842; G09G 2300/0861; G09G 2310/08; G09G 2320/0233; G09G 2320/0242; G09G 2320/0247; G09G 2320/041; G09G 2330/02

(57) ABSTRACT

The present disclosure provides a display panel and a display apparatus. The display panel includes a plurality of light-emitting elements, a plurality of pixel circuits, a plurality of first reference voltage lines, and a plurality of second reference voltage lines. The light-emitting elements include a first light-emitting element, a second light-emitting element and a third light-emitting element; and the pixel circuits include a first pixel circuit, a second pixel circuit and a third pixel circuit. A first reference voltage line is configured to provide a first reference voltage signal to the first light-emitting element and the third light-emitting element through the first pixel circuit and the third pixel circuit; a second reference voltage line is configured to provide a second reference voltage signal to the second light-emitting element through the second pixel circuit; and voltage values of the first reference voltage signal and the second reference voltage signal are different.

### CROSS-REFERENCE TO RELATED APPLICATION

The present disclosure claims the priority of Chinese Patent Application No. 202510612235.4, filed on May 13, 2025, the content of which is incorporated herein by reference in its entirety.

### TECHNICAL FIELD

The present disclosure generally relates to the field of display technology and, more particularly, relates to a display panel and a display apparatus.

### BACKGROUND

With continuous development of display technology, more display products, such as mobile phones, tablets, laptops, smart wearable devices and the like, are widely used, which may become an indispensable tool to bring great convenience.

Organic light-emitting diode display technology has been widely used in the field of consumer electronics due to advantages such as self-luminescence, high contrast, wide color gamut, thinness, flexibility and the like. However, organic light-emitting diode displays still face some challenges in actual use, especially the display quality still needs to be improved.

### SUMMARY

One aspect of the present disclosure provides a display panel. The display panel includes a plurality of light-emitting elements and a plurality of pixel circuits connected to the plurality of light-emitting elements, where the plurality of light-emitting elements includes a first light-emitting element, a second light-emitting element and a third light-emitting element; light-emitting colors of the first light-emitting element, the second light-emitting element and the third light-emitting element are different; the plurality of pixel circuits includes a first pixel circuit, a second pixel circuit and a third pixel circuit; the first pixel circuit is electrically connected to the first light-emitting element; the second pixel circuit is electrically connected to the second light-emitting element; and the third pixel circuit is electrically connected to the third light-emitting element. The display panel further includes a plurality of first reference voltage lines and a plurality of second reference voltage lines, where a first reference voltage line is configured to provide a first reference voltage signal to the first light-emitting element and the third light-emitting element through the first pixel circuit and the third pixel circuit, respectively; a second reference voltage line is configured to provide a second reference voltage signal to the second light-emitting element through the second pixel circuit; and a voltage value of the first reference voltage signal is different from a voltage value of the second reference voltage signal. The plurality of first reference voltage lines includes a plurality of first sub-reference voltage lines extending along a first direction and a plurality of second sub-reference voltage lines extending along a second direction, and a first sub-reference voltage line is electrically connected to a second sub-reference voltage line; and the plurality of second reference voltage lines includes a plurality of third sub-reference voltage lines extending along the first direction and a plurality of fourth sub-reference voltage lines extending along the second direction; a third sub-reference voltage line is electrically connected to a fourth sub-reference voltage line; and the first direction intersects the second direction.

Another aspect of the present disclosure provides a display apparatus including a display panel. The display panel includes a plurality of light-emitting elements and a plurality of pixel circuits connected to the plurality of light-emitting elements, where the plurality of light-emitting elements includes a first light-emitting element, a second light-emitting element and a third light-emitting element; light-emitting colors of the first light-emitting element, the second light-emitting element and the third light-emitting element are different; the plurality of pixel circuits includes a first pixel circuit, a second pixel circuit and a third pixel circuit; the first pixel circuit is electrically connected to the first light-emitting element; the second pixel circuit is electrically connected to the second light-emitting element; and the third pixel circuit is electrically connected to the third light-emitting element. The display panel further includes a plurality of first reference voltage lines and a plurality of second reference voltage lines, where a first reference voltage line is configured to provide a first reference voltage signal to the first light-emitting element and the third light-emitting element through the first pixel circuit and the third pixel circuit, respectively; a second reference voltage line is configured to provide a second reference voltage signal to the second light-emitting element through the second pixel circuit; and a voltage value of the first reference voltage signal is different from a voltage value of the second reference voltage signal. The plurality of first reference voltage lines includes a plurality of first sub-reference voltage lines extending along a first direction and a plurality of second sub-reference voltage lines extending along a second direction, and a first sub-reference voltage line is electrically connected to a second sub-reference voltage line; and the plurality of second reference voltage lines includes a plurality of third sub-reference voltage lines extending along the first direction and a plurality of fourth sub-reference voltage lines extending along the second direction; a third sub-reference voltage line is electrically connected to a fourth sub-reference voltage line; and the first direction intersects the second direction.

Other aspects of the present disclosure may be understood by those skilled in the art in the light of the description, the claims, and the drawings of the present disclosure.

### BRIEF DESCRIPTION OF THE DRAWINGS

The accompanying drawings, which are incorporated into a part of the specification, illustrate embodiments of the present disclosure and together with the description to explain the principles of the present disclosure.

To clearly explain embodiments of the present disclosure or the technical solutions in the existing technology, the drawings needed for describing embodiments or the existing technology are briefly introduced hereinafter. Obviously, the drawings in the following description are merely embodiments of the present disclosure. Other drawings may also be obtained by those skilled in the art without any creative work according to provided drawings.

FIG. 1 illustrates a planar schematic of a display panel according to various embodiments of the present disclosure.

FIG. 2 illustrates a connection schematic of a light-emitting element, a pixel circuit, a first reference voltage line and a second reference voltage line.

FIG. 3 illustrates a structural schematic of a pixel circuit according to various embodiments of the present disclosure.

FIG. 4 illustrates another structural schematic of a pixel circuit according to various embodiments of the present disclosure.

FIG. 5 illustrates a time sequence diagram of a pixel circuit in FIG. 3.

FIG. 6 illustrates an arrangement schematic of pixel circuits according to various embodiments of the present disclosure.

FIG. 7 illustrates an arrangement schematic of light-emitting elements according to various embodiments of the present disclosure.

FIG. 8 illustrates another connection schematic of a light-emitting element, a pixel circuit, a first reference voltage line and a second reference voltage line.

FIG. 9 illustrates a schematic of film layers of a display panel according to various embodiments of the present disclosure.

FIG. 10 illustrates a layout schematic of a circuit column group where a second sub-reference voltage line and a fourth sub-reference voltage line are located.

FIG. 11 illustrates another layout schematic of a circuit column group where a second sub-reference voltage line and a fourth sub-reference voltage line are located.

FIG. 12 illustrates another layout schematic of a circuit column group where a second sub-reference voltage line and a fourth sub-reference voltage line are located.

FIG. 13 illustrates another layout schematic of a circuit column group where a second sub-reference voltage line and a fourth sub-reference voltage line are located.

FIG. 14 illustrates another layout schematic of a circuit column group where a second sub-reference voltage line and a fourth sub-reference voltage line are located.

FIG. 15 illustrates another layout schematic of a circuit column group where a second sub-reference voltage line and a fourth sub-reference voltage line are located.

FIG. 16 illustrates another layout schematic of a circuit column group where a second sub-reference voltage line and a fourth sub-reference voltage line are located.

FIG. 17 illustrates a layout schematic of a first reference voltage line and a second reference voltage line in the display panel.

FIG. 18 illustrates another layout schematic of a first reference voltage line and a second reference voltage line in the display panel.

FIG. 19 illustrates a layout schematic of a second sub-reference voltage line, a fourth sub-reference voltage line, a third reference voltage line and a fourth reference voltage line.

FIG. 20 illustrates a connection schematic of a reference voltage line and a signal line in a frame region in a display panel.

FIG. 21 illustrates a structural schematic of a display apparatus according to various embodiments of the present disclosure.

### DETAILED DESCRIPTION

To clearly understand above-mentioned objectives, features and advantages of the present disclosure, the solutions of the present disclosure are further described hereinafter. It should be noted that embodiments of the present disclosure and the features in embodiments may be combined with each other if there is no conflict.

Specific details are described in following description to facilitate thorough understanding of the present disclosure, but the disclosure may also be implemented otherwise than as described herein. Obviously, embodiments in the description may be only a part of, not all, embodiments of the present disclosure.

Organic light-emitting diode (OLED) display technology has been widely used in the field of consumer electronics due to advantages such as self-luminescence, high contrast, wide color gamut, thinness, flexibility and the like. However, OLED displays still face certain challenges in actual usage, especially in terms of the stability of display quality. Two notable problems are heating color cast (deviation) and poor low grayscale visual effect. Heating color cast refers to that when the OLED display screen works for a long time or ambient temperature changes, the white balance of the screen may drift and color deviation may occur due to sensitivity difference of different color sub-pixels (red, green, and blue) to temperature, which may affect user's viewing experience. Poor low grayscale visual effect refers to that when displaying low-brightness images, the screen may have problems such as uneven brightness or even flickering, which may be related to the characteristics of the driving circuit itself (such as threshold voltage drift).

Based on the above, the present disclosure provides a display panel and a display apparatus, which may reduce the problems of heating color cast and poor low grayscale visual effect that may occur in the display panel, thereby improving the display quality.

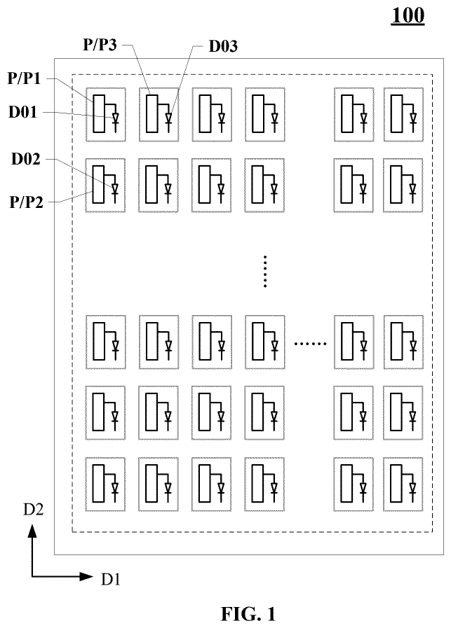

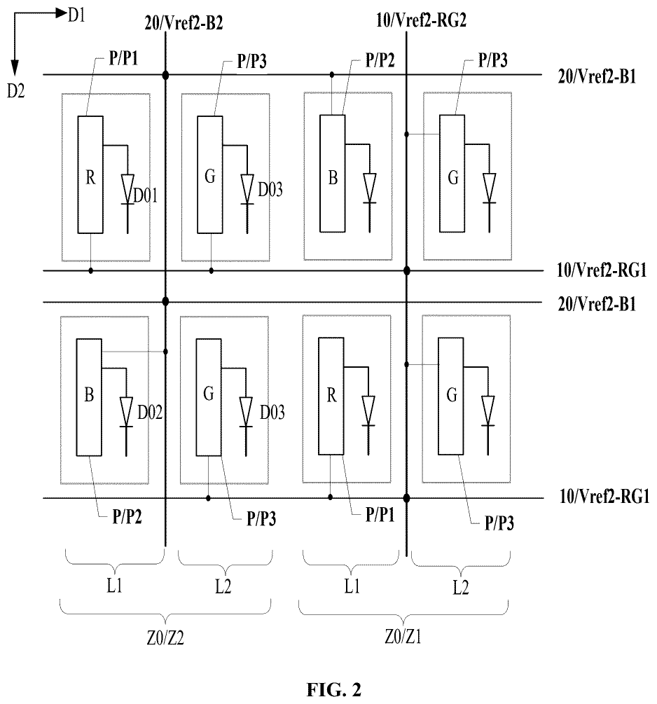

FIG. 1 illustrates a planar schematic of a display panel according to various embodiments of the present disclosure; and FIG. 2 illustrates a connection schematic of a light-emitting element, a pixel circuit, a first reference voltage line and a second reference voltage line. It should be noted that FIG. 1 may only take a display panel with a rectangular structure as an example, which may not limit actual shape of the display panel. In some other embodiments of the present disclosure, the display panel may also be embodied in any other feasible shape, such as a circle, a rounded rectangle or the like. Optionally, the display panel provided in one embodiment may be an organic light-emitting display panel, and corresponding light-emitting element may be an organic light-emitting element. Obviously, in some other embodiments of the present disclosure, the display panel may also be configured to be a display panel using inorganic light-emitting diode display technology, such as a Micro LED display panel, a Mini LED display panel or the like, which may be not limited in the present disclosure.

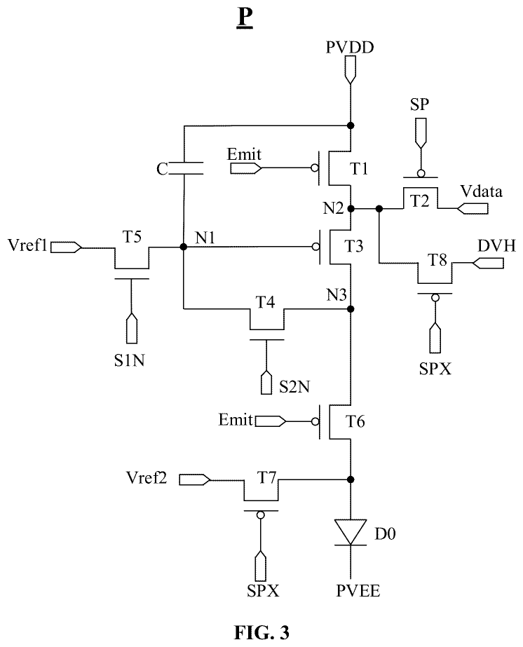

FIGS. 1-2 may be only block diagrams of pixel circuits. During an implementation, the structure of the pixel circuit may include a circuit structure of multiple transistors and capacitors which are electrically connected to each other. FIG. 3 illustrates a structural schematic of a pixel circuit according to various embodiments of the present disclosure. Taking FIG. 3 as an example, the pixel circuit may include a first transistor T1, a second transistor T2, a third transistor T3, a fourth transistor T4, a fifth transistor T5, a sixth transistor T6, a seventh transistor T7, an eighth transistor T8 and a capacitor C. The third transistor T3 may be a driving transistor configured to provide a driving current for a light-emitting element D0. The gate electrode, the first electrode and the second electrode of the driving transistor may be respectively connected to a first node N1, a third node N3 and a second node N2. The first electrode and the second electrode of the fifth transistor T5 may be respectively connected to a gate reset signal terminal Vref1 and the first node N1; and the gate electrode may be connected to a first control signal terminal S1N for receiving a reset control signal. The fifth transistor T5 may be configured to provide a gate reset signal to the first node N1. The first electrode and the second electrode of the second transistor T2 may be respectively connected to a data voltage signal terminal Vdata and the second node N2; and the gate electrode may receive a control signal SP. The second transistor T2 may be configured to transmit the data voltage signal Vdata to the second node N2. It should be noted that the signal terminal and the signal transmitted by the signal terminal in embodiments of the present disclosure are represented by same reference numerals (notations or marks). The first electrode and the second electrode of the fourth transistor T4 may be respectively connected to the third node N3 and the first node N1; and the gate electrode may be connected to the second control signal terminal S2N for receiving a control signal S2N. The fourth transistor T4 may be configured to perform threshold compensation on the third transistor T3. The first electrode and the second electrode of the seventh transistor T7 may be respectively connected to an anode reset signal terminal Vref2 and the first electrode of the light-emitting element D0; and the gate electrode may be connected to a control signal terminal SPX. The seventh transistor T7 may be configured to reset the first electrode (e.g., anode) of the light-emitting element D0. The first electrode and the second electrode of the eighth transistor T8 may be respectively connected to a bias adjustment signal terminal DVH and the second node N2; and the gate electrode may be connected to the control signal terminal SPX. The first electrode and the second electrode of the first transistor T1 may be respectively connected to a first power signal terminal PVDD and the second node N2; and the gate electrode may be connected to a light control signal terminal Emit. The first electrode and the second electrode of the sixth transistor T6 may be respectively connected to the third node N3 and the first electrode of the light-emitting element D0; and the gate electrode may be connected to the light-emitting control signal terminal Emit configured to transmit the driving current to the light-emitting element D0. The second electrode of the light-emitting element D0 may receive the second power supply signal PVEE. It should be noted that in embodiments of the present disclosure, exemplarily, the gate electrodes of the seventh transistor T7 and the eighth transistor T8 may be both connected to the control signal terminal SPX for illustration, which may not be limited in the present disclosure.

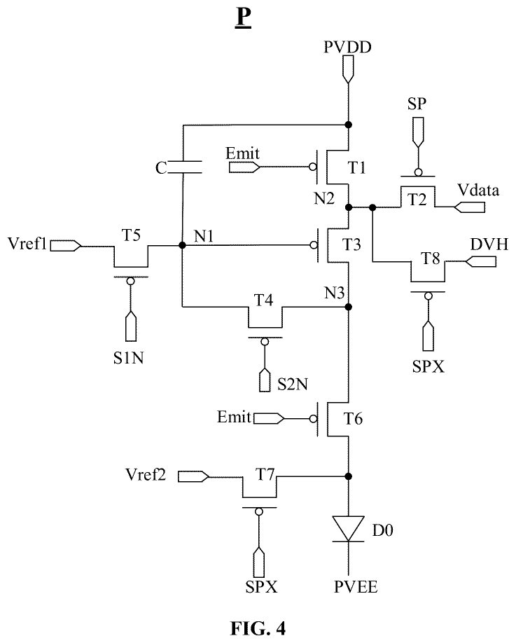

It should also be noted that the pixel circuit in FIG. 3 may be only for illustration, and the present disclosure may not limit the structure of the pixel circuit. In one embodiment of FIG. 3, the fourth transistor T4 and the fifth transistor T5 connected to the first node N1 may be N-type transistors which may be oxide transistors. The signal for controlling the conduction of the fourth transistor T4 and the fifth transistor T5 may be a high potential signal, and the other transistors may be all P-type transistors. In one embodiment, the fourth transistor T4 and the fifth transistor T5 may be N-type transistors. When the N-type transistors are oxide transistors, it is beneficial for reducing the leakage of the fourth transistor T4 and the fifth transistor T5 to the first node N1, thereby maintaining the stability of the potential of the gate electrode of the driving transistor connected to the first node N1. In some other embodiments, the pixel circuit may also be embodied in other structures. For example, referring to FIG. 4, FIG. 4 illustrates another structural schematic of a pixel circuit according to various embodiments of the present disclosure. The connection relationship and working principle in FIG. 4 may be same as the connection relationship and working principle in FIG. 3. The only difference between FIG. 3 and FIG. 4 may be that the fourth transistor T4 and the fifth transistor T5 may be P-type transistors. The P-type transistors may be turned on for conduction under the control of the low potential signal. When all transistors in one embodiment shown in FIG. 4 are P-type transistors, it is beneficial for simplifying the process of the pixel circuit.

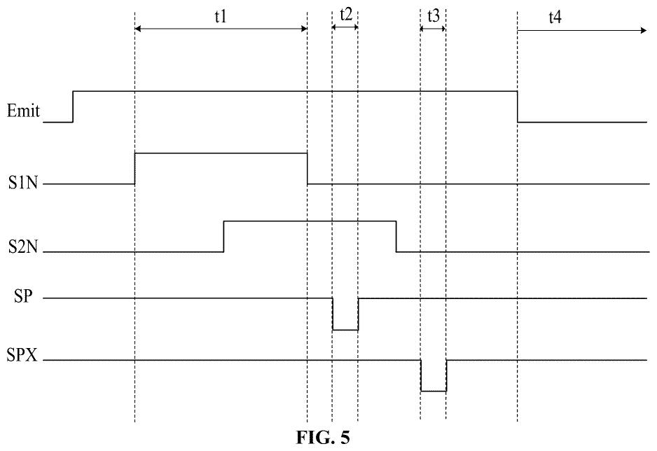

The working principle in FIG. 3 is described below in conjunction with FIG. 5. The working principle of the pixel circuit in FIG. 4 may refer to one embodiment in FIG. 5. FIG. 5 illustrates a time sequence diagram of a pixel circuit in FIG. 3. Referring to FIGS. 3 and 5, the working process of the pixel circuit P may include an initialization stage t1, a data writing and threshold compensation stage t2, a bias stage t3, and a light-emitting stage t4.

In the initialization stage t1, the high potential signal of the first control signal S1N may control the fifth transistor T5 to be turned on for conduction, and transmit the gate reset signal to the control terminal of the third transistor T3 for initialization, thereby eliminating residual charge of previous frame to improve the display effect of the display panel. In the present disclosure, in a part of the duration of the initialization stage t1, the effective levels of the first control signal S1N and the second control signal S2N may have overlap time, which may be beneficial for improving the hysteresis problem of the driving transistor during the initialization stage.

In the data writing and threshold compensation stage t2, the fifth transistor T5 may be turned off for disconnection, the control signal SP may control the second transistor T2 to be turned on for conduction, the second control signal S2N may control the fourth transistor T4 to be turned on for conduction, the data voltage signal Vdata may be written into the third transistor T3 through the second transistor T2, and the fourth transistor T4 may be connected between the gate electrode and the first electrode of the third transistor T3, and the threshold voltage of the third transistor T3 may be captured to the gate electrode of the third transistor T3, thereby achieving threshold voltage compensation and self-compensating of the threshold voltage deviation of the driving transistor.

In the bias stage t3, the control signal SPX may control the eighth transistor T8 to be turned on for conduction, and the bias adjustment signal DVH may be transmitted to the second electrode (i.e., the second node N2) of the driving transistor through the eighth transistor T8 to adjust the bias state of the driving transistor. Simultaneously, the control signal SPX may control the seventh transistor T7 to be turned on for conduction, and the anode reset signal Vref2 may be transmitted to the anode of the light-emitting element D0 through the seventh transistor T7 to reset the light-emitting element D0.

In the light-emitting stage t4, the second transistor T2, the fourth transistor T4, the fifth transistor T5 and the seventh transistor T7 may be all turned off for disconnection; the first transistor T1, the third transistor T3 and the sixth transistor T6 may be all turned on for conduction, and the driving current may be transmitted to the first electrode of the light-emitting element D0, and the light-emitting element D0 may emit light. It should be noted that the time sequence diagram of FIG. 5 may be only for illustration, which may be not limited in the present disclosure. In some other embodiments of the present disclosure, pixel circuits of different structures may correspond to different time sequences.

In one embodiment, the stage of resetting the anode of the light-emitting element D0 may be performed simultaneously with the bias stage, which may be not limited in the present disclosure. In some other embodiments of the present disclosure, the stage of resetting the anode of the light-emitting element D0 may also be performed in the initialization stage.

In practical applications, when resetting the anode of the light-emitting element D0, the anode reset signal Vref2 may be transmitted to the anode of the light-emitting element D0 through the seventh transistor T7, thereby reducing the anode voltage to low potential or zero potential and eliminating residual charge or leakage current that may cause the light-emitting element to emit light unexpectedly. Furthermore, considering that slight differences may be between the threshold voltages of light-emitting elements of different light-emitting colors and driving transistors on the display panel, resetting the anode of the light-emitting element to a known state before each frame may be beneficial for minimizing the impact of changes in the threshold voltage on the initial state of the pixel, thereby achieving more uniform brightness and color across entire screen, especially at low grayscales.

Referring to FIGS. 1-2, the display panel is provided in embodiments of the present disclosure. The display panel may include the light-emitting elements D0 and the pixel circuits P which is connected to the light-emitting elements D0. The structure of the pixel circuit P may refer to FIGS. 3-4. The light-emitting element D0 may include the first light-emitting element D01, the second light-emitting element D02 and the third light-emitting element D03. The first light-emitting element D01, the second light-emitting element D02 and the third light-emitting element D03 may have different light-emitting colors. The pixel circuits P may include the first pixel circuit P1, the second pixel circuit P2 and the third pixel circuit P3. The first pixel circuit P1 may be electrically connected to the first light-emitting element D01, the second pixel circuit P2 may be electrically connected to the second light-emitting element D02, and the third pixel circuit P3 may be electrically connected to the third light-emitting element D03.

The display panel may also include the plurality of first reference voltage lines 10 and the plurality of second reference voltage lines 20. The first reference voltage line 10 may be configured to respectively provide the first reference voltage signal to the first light-emitting element D01 and the third light-emitting element D03 through the first pixel circuit P1 and the third pixel circuit P3. The second reference voltage line 20 may be configured to provide the second reference voltage signal to the second light-emitting element D02 through the second pixel circuit P2. The voltage value of the first reference voltage signal may be different from the voltage value of the second reference voltage signal. It should be noted that the first reference voltage signal and the second reference voltage signal may be anode reset signals transmitted to corresponding light-emitting elements.

The plurality of first reference voltage lines 10 may include the first sub-reference voltage line Vref2-RG1 extending along the first direction D1 and the second sub-reference voltage line Vref2-RG2 extending along the second direction D2; and the first sub-reference voltage line Vref2-RG1 may be electrically connected to the second sub-reference voltage line Vref2-RG2. The plurality of second reference voltage lines 20 may include the third sub-reference voltage line Vref2-B1 extending along the first direction D1 and the fourth sub-reference voltage line Vref2-B2 extending along the second direction D2; and the third sub-reference voltage line Vref2-B1 may be electrically connected to the fourth sub-reference voltage line Vref2-B2. The first direction D1 may intersect the second direction D2.

The first reference voltage line 10 mentioned in embodiments of the present disclosure may be configured to provide the first reference voltage signal to the anodes of the first light-emitting element D01 and the third light-emitting element D03 to reset the anodes of the first light-emitting element D01 and the third light-emitting element D03; and the second reference voltage line 20 may be configured to provide the second reference voltage signal to the anode of the second light-emitting element D02 to reset the anode of the second light-emitting element D02.

In the display panel provided by embodiments of the present disclosure, considering that at least two light-emitting elements of different light-emitting colors have different sensitivities to temperature due to different material properties, the first reference voltage line 10 and the second reference voltage line 20 may be disposed respectively. The first reference voltage line 10 and the second reference voltage line 20 may respectively provide independent first and second reference voltage signals, which may achieve the reset of the anodes of different light-emitting elements. Therefore, the initial states of different light-emitting elements before emitting light may be more finely controlled. For example, the reference voltage corresponding to the light-emitting element, which is more sensitive to temperature, may be adjusted to ensure more stable starting points at different temperatures, thereby reducing the brightness drift caused by temperature change and finally reducing white balance deviation and reducing the problem of heating color cast. Moreover, by differentially designing the first reference voltage signal and the second reference voltage signal, more suitable initial conditions may be provided for light-emitting elements with large differences in material properties during the anode reset stage, such that subsequent driving voltage may more accurately control the brightness output of each color sub-pixel, thereby desirably maintaining the target color ratio and reducing color deviation caused by temperature.

Furthermore, for displaying at low grayscales, the driving voltage applied to the light-emitting element may be extremely close to the turn-on voltage of the light-emitting element, a slight voltage difference may result in obvious brightness changes or unevenness. Therefore, in the present disclosure, desirable reference voltage signals (such as more accurate reset voltages) may be provided for different light-emitting elements through the first reference voltage line 10 and the second reference voltage line 20, which may ensure that different light-emitting elements have predictable starting states at low grayscales. In such way, the output of different light-emitting elements at low brightness may be accurately controlled, which may ensure the light-emitting elements to accurately respond to small driving voltage changes, thereby being beneficial for reducing the problem of low grayscale color cast; and the starting states of different light-emitting elements at low brightness may be accurately controlled, which may also avoid the light leakage problem caused by signal interference between different light-emitting elements when the display panel displays monochrome pictures and due to different turn-on voltages of the light-emitting elements.

Moreover, the first reference voltage line 10 in the present disclosure may include the first sub-reference voltage line Vref2-RG1 and the second sub-reference voltage line Vref2-RG2 which are electrically connected and extend in different directions; and the second reference voltage line 20 may include the third sub-reference voltage line Vref2-B1 and the fourth sub-reference voltage line Vref2-B2 which are electrically connected and extend in different directions. The first reference voltage lines 10 and the second reference voltage lines 20 may form a mesh wiring structure in the display panel, respectively, which may be beneficial for reducing overall impedance of the first reference voltage lines 10 and reducing overall impedance of the second reference voltage lines 20, thereby being beneficial for reducing the voltage difference of the reference voltage signals during transmission, balancing the consistency of the reference voltage signals received by light-emitting elements of different positions and same light-emitting color, and further improving the display uniformity of the display panel.

Referring to FIGS. 1-2, in an optional embodiment of the present disclosure, the turn-on voltages of the first light-emitting element D01 and the third light-emitting element D03 may be both lower than the turn-on voltage of the second light-emitting element D02; and the voltage value of the first reference voltage signal may be lower than the voltage value of the second reference voltage signal.

In the process of forming the display panel, to save costs and reduce formation processes, same mask may be configured to simultaneously evaporate some film layers in the light-emitting elements of different colors, which may result in at least one common film layer in different light-emitting elements. The common film layer may be, for example, at least one of a hole injection layer, a hole transport layer, an electron transport layer, and an electron injection layer.

The light-emitting elements may have different turn-on voltages due to differences in light-emitting materials. For example, in the present disclosure, the turn-on voltages of the first light-emitting element D01 and the third light-emitting element D03 may be both relatively small and similar to each other, and the turn-on voltage of the second light-emitting element D02 may be relatively large. Under low grayscale visual effects, when the second light-emitting element D02 needs to be turned on for pure color display, due to the presence of above-mentioned common film layer, relatively large driving current corresponding to the second light-emitting element D02 may leak through the common film layer to other light-emitting elements, which may result in the light leakage problem of the first light-emitting element D01 or the third light-emitting element D03 which should not emit light. Therefore, in one embodiment, when the turn-on voltages of the first light-emitting element D01 and the third light-emitting element D03 are lower than the turn-on voltage of the second light-emitting element D02, the voltage value of the first reference voltage signal provided by the first light-emitting element D01 and the third light-emitting element D03 may be configured to be lower than the voltage value of the second reference voltage provided for the second light-emitting element D02; that is, the potentials of the first reference voltage corresponding to the first light-emitting element D01 and the second light-emitting element D02 may be relatively low. When the light-emitting element in the display panel emits light, the initial reference voltage may be charged to the target turn-on voltage (the voltage difference between the reference voltage and the turn-on voltage may be regarded as the cross-voltage value), and the light-emitting element may naturally be turned on. It may be understood that the light-emitting element may have a charging process in early stage of being turned-on, and the potential may be charged from the reference voltage signal transmitted by the reference voltage line to a turn-on voltage value, and the light-emitting element may then emit light. In one embodiment, the voltage value of the anode reset signal of the first light-emitting element D01 and the third light-emitting element D03 with relatively small turn-on voltage may be pulled down (that is, the voltage value of the first reference voltage signal may be smaller, and the potential may be lower). When the second light-emitting element D02 is turned on to implement monochrome screen display, the first light-emitting element D01 and the third light-emitting element D03 may be less likely to reach corresponding cross-voltage value than the second light-emitting element D02. Therefore, the first light-emitting element D01 and the third light-emitting element D03 may not be easily affected by leakage current, which may be beneficial for avoiding the light leakage problem of light-emitting elements and improving display quality.

Referring to FIGS. 1-2, in an optional embodiment of the present disclosure, the first light-emitting element D01 may be one of a red light-emitting element and a blue light-emitting element; the second light-emitting element D02 may be another one of the red light-emitting element and the blue light-emitting element; and the third light-emitting element D03 may be a green light-emitting element. It should be noted that in FIGS. 1-2, the first light-emitting element D01 is the red light-emitting element, and the second light-emitting element D02 is the blue light-emitting element, which may be taken as an example for illustration and may be not limited in the present disclosure.

Optionally, the first light-emitting element D01 may be the red light-emitting element, the second light-emitting element D02 may be the blue light-emitting element, and the third light-emitting element D03 may be the green light-emitting element. When the light-emitting elements mentioned in embodiments of the present disclosure are organic light-emitting diodes, the turn-on voltage of the red light-emitting element may be less than the turn-on voltage of the blue light-emitting element, and the turn-on voltage of the green light-emitting element may be less than the turn-on voltage of the blue light-emitting element. Therefore, when the second light-emitting element D02 with blue light color is turned on, since the turn-on voltage of the second light-emitting element D02 is greater than the turn-on voltages of the red light-emitting element and the green light-emitting element, red and/or green light may leak (appear) under the blue picture (screen), which may affect the display quality of the display screen. In one embodiment, the second light-emitting element D02 may be configured as the blue light-emitting element with relatively large turn-on voltage, and the first light-emitting element D01 and the third light-emitting element D03 may be configured as red light-emitting elements and green light-emitting elements with relatively small turn-on voltages. At this point, the voltage value of the first reference voltage signal corresponding to the red light-emitting element and the green light-emitting element may be pulled down. When the blue light-emitting element is turned on to implement the blue screen display, even if the anodes of the red light-emitting element and the green light-emitting element are charged due to the influence of the common film layer, the red light-emitting element and the green light-emitting element may be not easy to be turned on due to relatively large cross-voltage values, which may be beneficial for improving the light leakage problem of the red light-emitting element and/or the green light-emitting element under the blue picture.

Different colors of light-emitting materials have different energy level structures and electronic transition characteristics, which may directly affect the turn-on voltages of corresponding light-emitting elements. In addition to the differences in light-emitting materials, the turn-on voltage values may also be affected by various factors such as manufacturers, device structures and the like. Therefore, in one embodiment, the first light-emitting element D01 may be the red light-emitting element, the second light-emitting element D02 may be the blue light-emitting element, and the third light-emitting element D03 may be the green light-emitting element, which may be taken as an example for description. In some other embodiments of the present disclosure, the first light-emitting element D01 may also be embodied as the blue light-emitting element, the second light-emitting element D02 may also be embodied as the red light-emitting element, and the third light-emitting element D03 may also be embodied as the green light-emitting element. At this point, the red light-emitting element may have relatively high turn-on voltage; and the blue light-emitting element and the green light-emitting element may have relatively low turn-on voltages, which may be also applicable to the present disclosure.

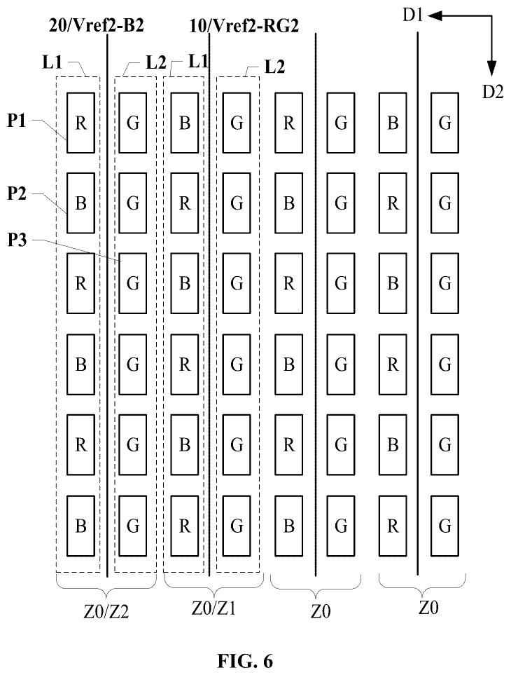

FIG. 6 illustrates an arrangement schematic of pixel circuits according to various embodiments of the present disclosure. Referring to FIG. 6, in an optional embodiment of the present disclosure, the display panel may include a plurality of first-type circuit columns L1 and a plurality of second-type circuit columns L2 which are arranged alternately along the first direction D1. The first-type circuit column L1 may include a plurality of first pixel circuits P1 and a plurality of second pixel circuits P2 which are arranged alternately along the second direction D2; and the second-type circuit column L2 may include a plurality of third pixel circuits P3 arranged along the second direction D2. The display panel may include a plurality of circuit column groups Z0 arranged along the first direction D1; one circuit column group Z0 may include the first-type circuit column L1 and the second-type circuit column L2 which are arranged to be adjacent to each other along the first direction D1; and the second sub-reference voltage line Vref2-RG2 and the fourth sub-reference voltage line Vref2-B2 may be respectively arranged to correspond to different circuit column groups Z0.

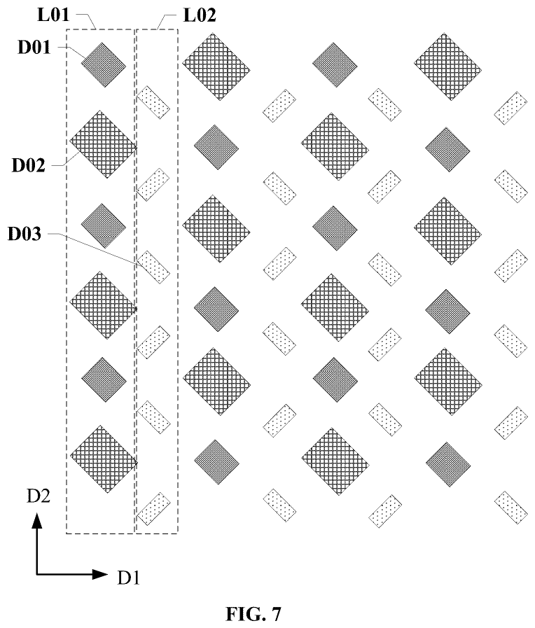

It should be noted that, in order to clearly illustrate overall arrangement of the second sub-reference voltage line Vref2-RG2 and the fourth sub-reference voltage line Vref2-B2 in the display panel, FIG. 6 only illustrates different pixel circuits in the circuit column group Z0 in the form of boxes, and distinguishes the first pixel circuit P1, the second pixel circuit P2 and the third pixel circuit P3 by R, B and G respectively. It should also be noted that FIG. 6 only illustrates the arrangement manner of the pixel circuits in the display panel, which may not limit the arrangement manner of the light-emitting elements. In practical applications, the arrangement manner of the light-emitting elements may be performed according to actual conditions. For example, referring to FIG. 7, FIG. 7 illustrates an arrangement schematic of light-emitting elements according to various embodiments of the present disclosure. Similar to the arrangement manner of the pixel circuits, the light-emitting elements may include the first element columns L01 and the second element columns L02 which are alternately arranged along the first direction D1; the first element column L01 may include the first light-emitting elements D01 and the second light-emitting elements D02 which are alternately arranged along the second direction D2; and the second element column L02 may include the plurality of third light-emitting elements D03 arranged along the second direction D2, which may not be limited in the present disclosure. It should be noted that the shape and size of the light-emitting element shown in FIG. 7 may be only exemplary, which may not be limited in the present disclosure.

In one embodiment, the first pixel circuit P1 and the second pixel circuit P2 in the first-type circuit column L1 may be configured to drive the first light-emitting element D01 and the second light-emitting element D02 respectively; and the third pixel circuit P3 in the second-type circuit column L2 may be configured to drive the third light-emitting element D03. Optionally, the third light-emitting element D03 may be the green light-emitting element; and one of the first light-emitting element D01 and the second light-emitting element D02 may be the red light-emitting element, and another one of the first light-emitting element D01 and the second light-emitting element D02 may be the blue light-emitting element. Optionally, the arrangement rule of the light-emitting elements may be adapted to the arrangement rule of corresponding pixel circuits. That is, in the display panel, when the first pixel circuits P1 and the second pixel circuits P2 in the first-type circuit column L1 are alternately arranged along the second direction D2, the first light-emitting elements D01 and the second light-emitting elements D02 may be also alternately arranged along the second direction D2 correspondingly; and when the plurality of third pixel circuits P3 in the second-type circuit column L2 are arranged along the second direction D2, the plurality of third light-emitting elements D03 in the display panel may be also arranged along the second direction D2. Considering that green contributes the most to the brightness perceived by the human eye, the second-type circuit column L2 may be independently configured to drive corresponding green light-emitting element, which may be beneficial for improving overall brightness of the display panel.

The circuit column group Z0 mentioned in one embodiment may include one first-type circuit column L1 and one second-type circuit column L2 which are arranged to be adjacent to each other along the first direction D1. Different circuit column groups Z0 may correspond to different circuit columns; that is, different circuit column groups Z0 may not share the first-type circuit column L1 or the second-type circuit column L2. The second sub-reference voltage line Vref2-RG2 in the first reference voltage line 10 and the fourth sub-reference voltage line Vref2-B2 in the second reference voltage line 20 may both extend along the second direction D2. At this point, the second sub-reference voltage line Vref2-RG2 and the fourth sub-reference voltage line Vref2-B2 may be respectively configured to correspond to different circuit column groups Z0, which may be beneficial for improving overall wiring uniformity of the second sub-reference voltage line Vref2-RG2 and the fourth sub-reference voltage line Vref2-B2 in the display panel.

Referring to FIG. 2, in an optional embodiment of the present disclosure, in the circuit column group Z1 where the second sub-reference voltage line Vref2-RG2 is located, at least one of the first pixel circuit P1 and the third pixel circuit P3 may be electrically connected to the second sub-reference voltage line Vref2-RG2, and the second pixel circuit P2 may be electrically connected to the third sub-reference voltage line Vref2-B1.

The circuit column group Z1 where the second sub-reference voltage line Vref2-RG2 mentioned in one embodiment is located may refer to the circuit column group where the second sub-reference voltage line Vref2-RG2 is configured but the fourth sub-reference voltage line Vref2-B2 is not configured. The second sub-reference voltage line Vref2-RG2 may belong to a part of the first reference voltage line 10; and the first reference voltage line 10 may be configured to provide the first reference voltage signal to the first light-emitting element D01 and the third light-emitting element D03 through the first pixel circuit P1 and the third pixel circuit P3 respectively. Therefore, in the circuit column group Z1 where the second sub-reference voltage line Vref2-RG2 is located, at least one of the first pixel circuit P1 and the third pixel circuit P3 may be electrically connected to the second sub-reference voltage line Vref2-RG2 to obtain the first reference voltage signal from the second sub-reference voltage line Vref2-RG2. It should be noted that in one embodiment of FIG. 2, it may only illustrate the solution that only the third pixel circuit P3 is electrically connected to the second sub-reference voltage line Vref2-RG2 in the circuit column group Z1 where the second sub-reference voltage line Vref2-RG2 is located. Obviously, in some other embodiments of the present disclosure, only the first pixel circuit P1 may be electrically connected to the second sub-reference voltage line Vref2-RG2, or both the first pixel circuit P1 and the third pixel circuit P3 may be electrically connected to the second sub-reference voltage line Vref2-RG2, which may be described in subsequent embodiments.

For the circuit column group Z1 where the second sub-reference voltage line Vref2-RG2 is located, since the fourth sub-reference voltage line Vref2-B2 extending along the second direction D2 is not configured, the second pixel circuit P2 may be electrically connected to the third sub-reference voltage line Vref2-B1 extending along the first direction D1, and obtain the second reference voltage signal through the third sub-reference voltage line Vref2-B1.

In various embodiments of the present disclosure, the first reference voltage line 10 may include the first sub-reference voltage line Vref2-RG1 extending along the first direction D1 and the second sub-reference voltage line Vref2-RG2 extending along the second direction D2; and the second reference voltage line 20 may include the third sub-reference voltage line Vref2-B1 extending along the first direction D1 and the fourth sub-reference voltage line Vref2-B2 extending along the second direction D2. When the second sub-reference voltage line Vref2-RG2 and the fourth sub-reference voltage line Vref2-B2 extending along the second direction D2 correspond to different circuit column groups Z0, the first pixel circuit P1, the second pixel circuit P2 and the third pixel circuit P3 may be electrically connected to corresponding sub-reference voltage lines through a nearest connection manner, which may simplify the wiring difficulty of the display panel. The connection manner between the pixel circuits and the sub-reference voltage lines is further described in subsequent embodiments.

Referring to FIG. 2, in an optional embodiment of the present disclosure, in the circuit column group Z1 where the second sub-reference voltage line Vref2-RG2 is located, the first pixel circuit P1 may be electrically connected to the first sub-reference voltage line Vref2-RG1 extending along the first direction D1, and the third pixel circuit P3 may be electrically connected to the second sub-reference voltage line Vref2-RG2 extending along the second direction D2.

In the circuit column group Z1 where the second sub-reference voltage line Vref2-RG2 is located, the first pixel circuit P1 may be in the first-type circuit column L1. In the first-type circuit column L1, the first pixel circuit P1 and the second pixel circuit P2 may be alternately arranged along the second direction D2. The first pixel circuit P1 may be electrically connected to the first sub-reference voltage line Vref2-RG1 extending along the first direction D1, and the second pixel circuit P2 may be electrically connected to the third sub-reference voltage line Vref2-B1 extending along the first direction D1. In the second-type circuit column L2, each third pixel circuit P3 may be electrically connected to the second sub-reference voltage line Vref2-RG2 extending along the second direction D2. In one embodiment, in the circuit column group Z1 where the second sub-reference voltage line Vref2-RG2 is located, the first pixel circuit P1 may be electrically connected to the first sub-reference voltage line Vref2-RG1 extending along the first direction D1, and the third pixel circuit P3 may be electrically connected to the second sub-reference voltage line Vref2-RG2 extending along the second direction D2, which may be beneficial for balancing the loads corresponding to the first sub-reference voltage line Vref2-RG1 and the second sub-reference voltage line Vref2-RG2, thereby being beneficial for improving the transmission quality of the first reference voltage signal on the first sub-reference voltage line Vref2-RG1 and the second sub-reference voltage line Vref2-RG2.

Furthermore, both the first sub-reference voltage line Vref2-RG1 and the second sub-reference voltage line Vref2-RG2 may need to obtain signals from a binding region of the display panel (for electrical connection with a control chip). It is assumed that the binding region is in the extension direction of the second sub-reference voltage line Vref2-RG2. Therefore, the signal transmission distance between the second sub-reference voltage line Vref2-RG2 and the binding region may be relatively short, and the second sub-reference voltage line Vref2-RG2 may transmit the first reference voltage signal faster than the first sub-reference voltage line Vref2-RG1. When the third light-emitting element D03 corresponding to the third pixel circuit P3 is the green light-emitting element, since the green light-emitting element contributes the most to the brightness perception of the human eye, the anode reset of the third light-emitting element D03 corresponding to the third pixel circuit P3 may be achieved more quickly when the third pixel circuit P3 is connected to the second sub-reference voltage line Vref2-RG2 extending along the second direction D2, which may be beneficial for reducing the smear and blur of overall picture.

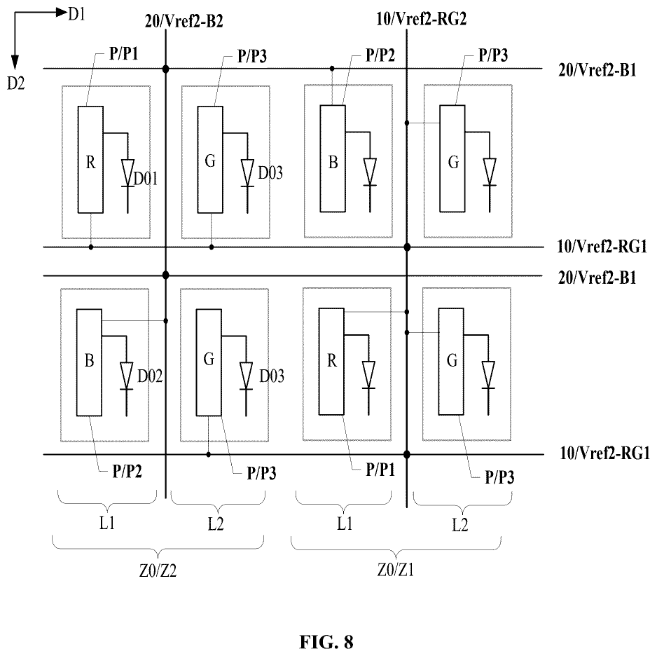

FIG. 8 illustrates a connection schematic of the light-emitting element, the pixel circuit, the first reference voltage line and the second reference voltage line. The difference from one embodiment of FIG. 2 may be that in the circuit column group Z1 where the second sub-reference voltage line Vref2-RG2 is located, the first pixel circuit P1 may be electrically connected to the second sub-reference voltage line Vref2-RG2.

Referring to FIG. 8, in an optional embodiment of the present disclosure, in the circuit column group Z1 where the second sub-reference voltage line Vref2-RG2 is located, the first pixel circuit P1 and the third pixel circuit P3 may be both electrically connected to the second sub-reference voltage line Vref2-RG2.

In one embodiment, it describes the solution that in the circuit column group Z0 where the second sub-reference voltage line Vref2-RG2 is located, the first pixel circuit P1 and the third pixel circuit P3 may be both connected to the second sub-reference voltage line Vref2-RG2 extending along the second direction D2. In such way, for the first pixel circuit P1 and the third pixel circuit P3 in same row, both the first pixel circuit P1 and the third pixel circuit P3 may receive the anode reset signal simultaneously, thereby realizing the synchronous reset of the first light-emitting element D01 and the third light-emitting element D03.

Furthermore, both the first sub-reference voltage line Vref2-RG1 and the second sub-reference voltage line Vref2-RG2 may need to obtain signals from the binding region of the display panel. It is assumed that the binding region is in the extension direction of the second sub-reference voltage line Vref2-RG2, such that the second sub-reference voltage line Vref2-RG2 may transmit the first reference voltage signal faster than the first sub-reference voltage line Vref2-RG1. Therefore, in one embodiment, when the first pixel circuit P1 and the third pixel circuit P3 are both connected to the second sub-reference voltage line Vref2-RG2 extending along the second direction D2, the distance for signal transmission from the binding region to the second sub-reference voltage line Vref2-RG2 may be relatively short, and the signal attenuation may be relatively small, which may be beneficial for realizing rapid reset of the first light-emitting element D01 and the third light-emitting element D03 corresponding to the first pixel circuit P1 and the third pixel circuit P3, thereby being beneficial for quickly clearing the residual charge and preparing for the display of next frame.

Referring to FIG. 8, in an optional embodiment of the present disclosure, in the circuit column group Z2 where the fourth sub-reference voltage line Vref2-B2 is located, the second pixel circuit P2 may be electrically connected to the fourth sub-reference voltage line Vref2-B2; and the first pixel circuit P1 and the third pixel circuit P3 may be electrically connected to the first sub-reference voltage line Vref2-RG1.

For the circuit column group Z2 where the fourth sub-reference voltage line Vref2-B2 is located, the fourth sub-reference voltage line Vref2-B2 may extend along the second direction D2. When the second pixel circuit P2 is electrically connected to the fourth sub-reference voltage line Vref2-B2, the second pixel circuit P2 may obtain the second reference voltage signal through the fourth sub-reference voltage line Vref2-B2. The third sub-reference voltage line Vref2-B1 and the fourth sub-reference voltage line Vref2-B2 in the second reference voltage line 20 may both need to obtain signals from the binding region of the display panel. It is assumed that the binding region is in the extension direction of the fourth sub-reference voltage line Vref2-B2, such that the fourth sub-reference voltage line Vref2-B2 may transmit the second reference voltage signal faster than the third sub-reference voltage line Vref2-B1. Therefore, in one embodiment, when the second pixel circuit P2 is connected to the fourth sub-reference voltage line Vref2-B2 extending along the second direction D2, the distance of signal transmission from the binding region to the fourth sub-reference voltage line Vref2-B2 may be relatively short, the signal attenuation may be relatively small, which may be beneficial for realizing rapid reset of the second light-emitting element D02 corresponding to the second pixel circuit P2, thereby being beneficial for quickly clearing the residual charge and preparing for the display of next frame.

It should be noted that in the circuit column group Z2 where the fourth sub-reference voltage line Vref2-B2 is located, the second sub-reference voltage line Vref2-RG2 extending along the second direction D2 may be not configured, such that the first pixel circuit P1 and the third pixel circuit P3 may be both electrically connected to the first sub-reference voltage line Vref2-RG1 extending along the first direction D1 to obtain the first reference voltage signal, thereby avoiding complicated wiring problem caused by connecting to the second sub-reference voltage line Vref2-RG2 which is far away from above pixel circuits.

It should be noted that in embodiments of FIGS. 2 and 8, the circuit column group Z0 where the second sub-reference voltage line Vref2-RG2 is located may be configured to be adjacent to the circuit column group Z0 where the fourth sub-reference voltage line Vref2-B2 is located, which may not be limited in the present disclosure. In some other embodiments of the present disclosure, the circuit column group Z0 where the second sub-reference voltage line Vref2-RG2 is located may be not adjacent to the circuit column group Z0 where the fourth sub-reference voltage line Vref2-B2 is located.

It should be noted that FIGS. 2 and 8 may only illustrate the connection of the first reference voltage line 10 and the second reference voltage line 20 with the pixel circuits, which may not limit the film layers of above-mentioned signal lines. The film layer structure of the display panel is described hereinafter.

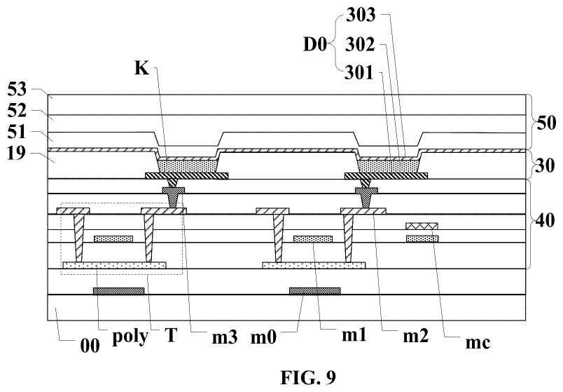

FIG. 9 illustrates a schematic of film layers of a display panel according to various embodiments of the present disclosure. The display panel may be an OLED display panel as an example for description. It should be noted that in one embodiment, the transistors in the pixel circuit may be P-type transistors, which may be taken as an example for description and may not be limited in the present disclosure. Referring to FIG. 9. Basic structure of the light-emitting element D0 may include an anode 301, a light-emitting material layer 302 and a cathode 303. When the power supply supplies a suitable voltage, the holes generated by the anode 301 and the electrons generated by the cathode 303 may combine in the light-emitting material layer 302 to generate bright light. Optionally, the display panel may include a substrate 00, a driving layer 40, and a display layer 30. The display layer 30 may include a pixel definition layer 19, and the pixel definition layer 19 may define a plurality of pixel openings K. The light-emitting material layer 302 may be at least in the pixel opening K. Along the direction perpendicular to the substrate 00, the anode 301 and the cathode 303 may be respectively located on two sides of the light-emitting material layer 302, and the anode 301 may be on the side of the cathode 303 facing the substrate 00. Optionally, an encapsulation layer 50 may be further configured on the side of the cathode 303 away from the anode 301. Optionally, the encapsulation layer 50 may include a first inorganic layer 51, an organic layer 52 and a second inorganic layer 53 which are stacked with each other. Above-mentioned pixel circuit may be configured in the driving layer 40 for providing the driving voltage to the light-emitting element D0, thereby driving the light-emitting element to emit light. The pixel circuit may include a plurality of transistors T. Optionally, in the driving layer 40, the gate electrode of the transistor may be configured at the first metal layer m1, and the source and drain of the transistor may be configured at the second metal layer m2. Optionally, the array substrate 10 may further include an active layer poly configured on the side of the first metal layer m1 facing the substrate 00 and an auxiliary metal layer m0 configured on the side of the active layer poly facing the substrate 00. Along the direction perpendicular to the plane where the substrate 00 is located, the first metal layer m1 and the auxiliary metal layer m0 may be both overlapped with the active layer poly; and the auxiliary metal layer m0 may have the light blocking effect to prevent the light from affecting the active layer poly. Optionally, a capacitor metal layer mc may be further included between the first metal layer m1 and the second metal layer m2; and the capacitor metal layer mc may form a capacitor structure with the second metal layer m2 or the first metal layer m1. Optionally, a third metal layer m3 may be also configured on the side of the second metal layer m2 away from the substrate 00. Another metal layer may be configured on the side of the third metal layer m3 away from the substrate according to actual needs, which may be not limited in the present disclosure. Each metal layer may be configured with signal lines.

The first sub-reference voltage line Vref2-RG1 and the third sub-reference voltage line Vref2-B1 mentioned in embodiments of the present disclosure may be configured in the first metal layer m1 or the capacitor metal layer mc mentioned above, or other feasible film layers. The first sub-reference voltage line Vref2-RG1 and the third sub-reference voltage line Vref2-B1 may be configured in same layer or in different layers. The second reference voltage line 20 and the fourth reference voltage line DVH may be configured in the second metal layer m2 or the capacitor metal layer mc mentioned above, or other feasible film layers. The second reference voltage line 20 and the fourth reference voltage line DVH may be configured in same layer or in different layers, which may be not limited in the present disclosure.

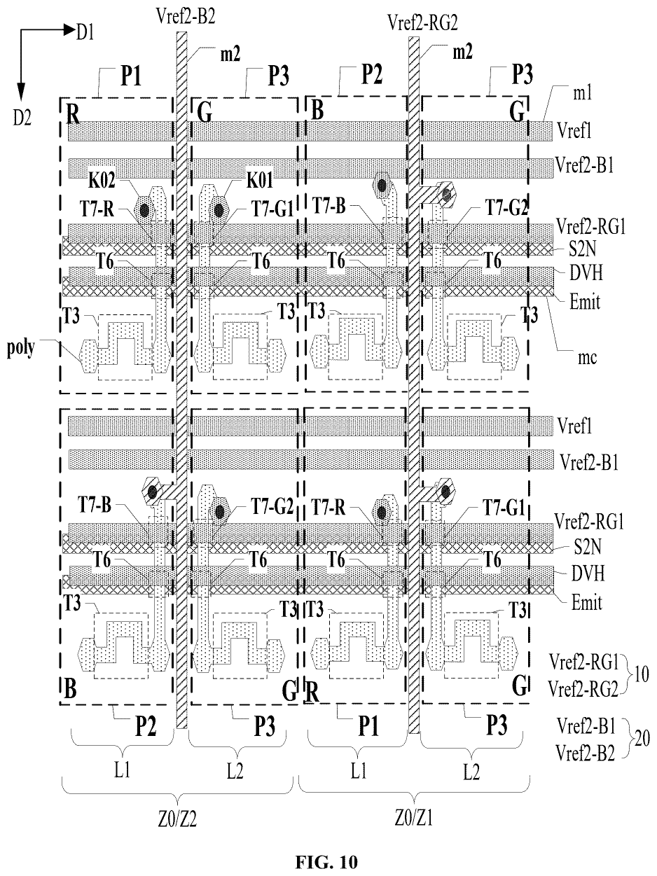

FIG. 10 illustrates a layout schematic of the circuit column group where the second sub-reference voltage line Vref2-RG2 and the fourth sub-reference voltage line Vref2-B2 are located. In one embodiment, it describes the solution that the circuit column group Z1 where the second sub-reference voltage line Vref2-RG2 is located may be adjacent to the circuit column group Z2 where the fourth sub-reference voltage line Vref2-B2 is located, which may not be limited in the present disclosure. Referring to FIGS. 4 and 10, in an optional embodiment of the present disclosure, the pixel circuit may include the first reset transistor T7 (corresponding to the seventh transistor T7 in one embodiment of FIG. 4), the first end of the first reset transistor T7 may be connected to the first reference voltage line 10 or the second reference voltage line 20, and the second end of the first reset transistor T7 may be connected to the anode of the light-emitting element; in the second-type circuit column L2, the first reset transistors T7 corresponding to adjacent third pixel circuits P3 along the second direction D2 may be respectively the first sub-transistor T7-G1 and the second sub-transistor T7-G2; in the circuit column group Z0, along the first direction D1, the first sub-transistor T7-G1 may be adjacent to the first reset transistor T7-R in the first pixel circuit P1; and the second sub-transistor T7-G2 may be adjacent to the first reset transistor T7-B in the second pixel circuit P2.

It should be noted that, for the convenience of description, the first reset transistors T7 corresponding to adjacent third pixel circuits P3 in the second-type circuit column L2 may be defined as the first sub-transistor T7-G1 and the second sub-transistor T7-G2 respectively in one embodiment, but the structures or performance of the first sub-transistor T7-G1 and the second sub-transistor T7-G2 may be not distinguished. In one embodiment, the first sub-transistor T7-G1 and the second sub-transistor T7-G2 may have same structure and play same role in different third pixel circuits P3. In the circuit column group Z1 where the second reference voltage line 20 is located, and in the circuit column group Z2 where the fourth reference voltage line DVH is located, the first sub-transistor T7-G1 may be regarded as the transistor configured to be adjacent to the first reset transistor T7-R in the first pixel circuit P1, and the second sub-transistor T7-G2 may be regarded as the transistor configured to be adjacent to the first reset transistor T7-B in the second pixel circuit P2.

In one embodiment, in same circuit column group Z0, the first reset transistors T7 corresponding to two adjacent pixel circuits along the first direction D1 may be configured to be adjacent to each other, such that two adjacent first reset transistors T7 may have similar electrical characteristics (such as threshold voltage and mobility). For the first pixel circuit P1 and the third pixel circuit P3 receiving same first reference voltage signal, the first reference voltage signals transmitted by corresponding two first reset transistors T7 may be more uniform or consistent, thereby being beneficial for resetting the anodes of the light-emitting elements corresponding to the first pixel circuit P1 and the third pixel circuit P3 to more stable starting state, reducing the brightness drift caused by temperature changes, and finally reducing the offset (deviation) of the white balance and reducing the problem of heating color cast.

Furthermore, in same circuit column group Z0, the first reset transistors T7 corresponding to two adjacent pixel circuits along the first direction D1 may be configured to be adjacent to each other, such that at least a part of adjacent first reset transistors T7 may share the second sub-reference voltage line Vref2-RG2 or the fourth sub-reference voltage line Vref2-B2 extending along the second direction D2, which may be beneficial for simplifying the connection complexity of the first reset transistor T7 and corresponding second sub-reference voltage line Vref2-RG2 or corresponding fourth sub-reference voltage line Vref2-B2. Meanwhile, in same circuit column group Z0, the first reset transistors T7 corresponding to two adjacent pixel circuits along the first direction D1 may be configured to be adjacent to each other, which may be beneficial for achieving more compact pixel arrangement, implementing higher pixel density under same physical size and improving the display resolution and fineness.

Referring to FIG. 10, in an optional embodiment of the present disclosure, in the circuit column group Z1 corresponding to the second sub-reference voltage line Vref2-RG2, the first reset transistor T7-R/T7-B and the first sub-transistor T7-G1 or the second sub-transistor T7-G2 which is adjacent to the first reset transistor T7-R/T7-B may be respectively on two sides of the second sub-reference voltage line Vref2-RG2; and in the circuit column group Z2 where the fourth sub-reference voltage line Vref2-B2 is located, the first reset transistor T7-R/T7-B and the first sub-transistor T7-G1 or the second sub-transistor T7-G2 which is adjacent to the first reset transistor T7-R/T7-B may be respectively on two sides of the fourth sub-reference voltage line Vref2-B2.

In the circuit column group Z1 where the second sub-reference voltage line Vref2-RG2 is located, when the first reset transistors T7 corresponding to two adjacent pixel circuits along the first direction D1 are configured to be adjacent to each other, the second reference voltage line 20 may be between two first reset transistors T7 adjacent to each other along the first direction D1, that is, between the first sub-transistor T7-G1 and the first reset transistor T7-R in the first pixel circuit P1 adjacent to the first sub-transistor T7-G1, and between the second sub-transistor T7-G2 and the first reset transistor T7-B in the second pixel circuit P2 adjacent to the second sub-transistor T7-G2. In such way, in the circuit column group Z1, at least one of the first sub-transistor T7-G1 and the first reset transistor T7-R adjacent to the first sub-transistor T7-G1 may be electrically connected to nearby second sub-reference voltage line Vref2-RG2, and, the second sub-transistor T7-G2 may also be electrically connected to nearby second sub-reference voltage line Vref2-RG2, which may be beneficial for simplifying the connection and wiring difficulty of the second sub-reference voltage line Vref2-RG2 and the transistor connected to the second sub-reference voltage line Vref2-RG2. Furthermore, when the binding region of the display panel is in the extension direction of the second sub-reference voltage line Vref2-RG2, the second sub-reference voltage line Vref2-RG2 may obtain the first reference voltage signal from the binding region more quickly, and quickly transmit the first reference voltage signal to the first reset transistor T7 connected thereto, such that the anode reset of the light-emitting elements corresponding to above first reset transistors T7 may be realized more quickly, which may be beneficial for reducing the smear and blur of overall picture.

In the circuit column group Z2 where the fourth sub-reference voltage line Vref2-B2 is located, when the first reset transistors T7 corresponding to two adjacent pixel circuits along the first direction D1 are configured to be adjacent to each other, the fourth reference voltage line DVH may be between two first reset transistors T7 adjacent to each other along the first direction D1, that is, between the first sub-transistor T7-G1 and the first reset transistor T7-R in the first pixel circuit P1 adjacent to the first sub-transistor T7-G1, and between the second sub-transistor T7-G2 and the first reset transistor T7-B in the second pixel circuit P2 adjacent to the second sub-transistor T7-G2. In such way, in the circuit column group Z2, the first reset transistor T7-B in the second pixel circuit P2 may be connected to nearby fourth sub-reference voltage line Vref2-B2, which may be beneficial for simplifying the connection difficulty of the fourth sub-reference voltage line Vref2-B2 and the first reset transistor T7-B connected to the fourth sub-reference voltage line Vref2-B2. Meanwhile, when the binding region of the display panel is in the extension direction of the fourth sub-reference voltage line Vref2-B2, the fourth sub-reference voltage line Vref2-B2 may obtain the second reference voltage signal from the binding region more quickly and quickly transmit the second reference voltage signal to the first reset transistor T7-B connected to the fourth sub-reference voltage line Vref2-B2, such that the anode reset of the second light-emitting element D02 corresponding to above first reset transistors T7-B may be realized more quickly, which may be beneficial for reducing the smear and blur of overall picture.

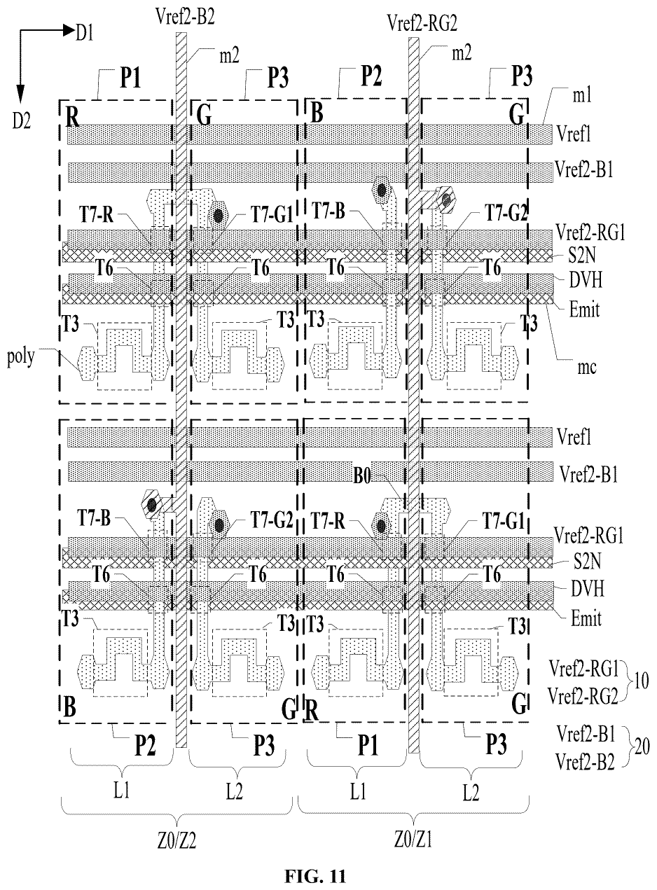

FIG. 11 illustrates another layout schematic of the circuit column group where the second sub-reference voltage line Vref2-RG2 and the fourth sub-reference voltage line Vref2-B2 are located. Referring to FIG. 11, in an optional embodiment of the present disclosure, in the circuit column group Z0, the first end of the first sub-transistor T7-G1 and the first end of the first reset transistor T7-R adjacent to the first sub-transistor T7-G1 may be electrically connected to each other through a connection portion B0.

The first reset transistors T7 in the first pixel circuit P1 and the third pixel circuit P3 may be both electrically connected to the first reference voltage line 10 and obtain the first reference voltage signal from the first reference voltage line 10. In the circuit column group Z0 of the present embodiment, when the first end of the first sub-transistor T7-G1 corresponding to the third pixel circuit P3 is electrically connected to the first reset transistor T7-R adjacent to the first sub-transistor T7-G1 through the connection portion B0, the first sub-transistor T7-G1 and the first reset transistor T7-R adjacent to the first sub-transistor T7-G1 may be connected to same sub-reference voltage line through the connection portion B0. For example, for the circuit column group Z1 where the second sub-reference voltage line Vref2-RG2 is located, the first sub-transistor T7-G1 and the first reset transistor T7-R adjacent to the first sub-transistor T7-G1 may be connected to the second sub-reference voltage line Vref2-RG2 or the first sub-reference voltage line Vref2-RG1 through the connection portion B0 (FIG. 11 illustrates the solution that the connection portion B0 is connected to the first sub-reference voltage line Vref2-RG1). For the circuit column group Z2 where the fourth sub-reference voltage line Vref2-B2 is located, the first sub-transistor T7-G1 and the first reset transistor T7-R adjacent to the first sub-transistor T7-G1 may be connected to the first sub-reference voltage line Vref2-RG1 through above-mentioned connection portion B0, such that there is no need to dispose different connection portions for the first sub-transistor T7-G1 and the first reset transistor T7-R adjacent to the first sub-transistor T7-G1 respectively and realize the connection with corresponding sub-reference voltage line through two punching processes, thereby reducing the connection difficulty of the first reset transistor T7 and the reference voltage line in the display panel and simplifying the connection process.

It should be noted that when the first end of the first sub-transistor T7-G1 is electrically connected to the first end of the first reset transistor T7-R adjacent to the first sub-transistor T7-G1 through the connection portion B0, the connection portion B0 may be in the active layer poly. The electrical connection between above two first ends may be implemented in the active layer poly, such that the metal layer in the display panel may be not occupied. In integrated circuit manufacturing, metal layers may be configured for long-distance signal and power wiring. In local regions, especially inside pixel circuits, arranging the connection portion B0 in the active layer poly may reduce the demand for metal wiring layers. Reducing the use of metal layers may also reduce required photolithography steps, thereby simplifying the layout design and reducing the formation complexity and cost. Furthermore, if two transistors are physically very close to each other, using the connection portion B0 in the active layer to directly connect corresponding first ends may avoid auxiliary connection through metal vias and metal layers. Each additional metal via may introduce additional resistance. Using the connection portion B0 directly in the active layer for connection may reduce contact resistances, thereby reducing overall connection resistance and being beneficial for improving the performance and efficiency of the circuit.

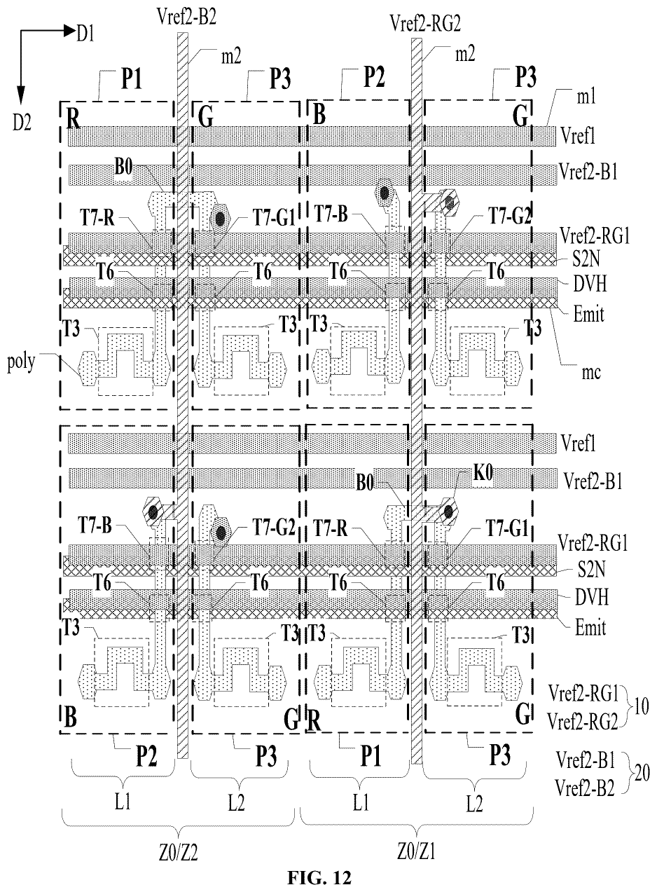

FIG. 12 illustrates a layout schematic of the circuit column group where the second sub-reference voltage line Vref2-RG2 and the fourth sub-reference voltage line Vref2-B2 are located. The difference from one embodiment of FIG. 11 may be that in the circuit column group Z1 where the second sub-reference voltage line Vref2-RG2 is located, the sub-reference voltage signal line connected to the connection portion B0 may be different. Referring to FIG. 12, in an optional embodiment of the present disclosure, in the circuit column group Z1 where the second sub-reference voltage line Vref2-RG2 is located, the connection portion B0 may be electrically connected to the second sub-reference voltage line Vref2-RG2 through a connection hole K0.

When the first sub-transistor T7-G1 is electrically connected to the first end of adjacent first reset transistor T7-R through the connection portion B0, in the circuit column group Z1 where the second sub-reference voltage line Vref2-RG2 is located, the connection portion B0 may be further electrically connected to the second sub-reference voltage line Vref2-RG2 extending along the second direction D2, and obtain the first reference voltage signal through the second sub-reference voltage line Vref2-RG2. When the binding region is in the extension direction of the second sub-reference voltage line Vref2-RG2, the signal transmission distance between the second sub-reference voltage line Vref2-RG2 and the binding region may be relatively short. That is, the signal transmission distance from the binding region to the second sub-reference voltage line Vref2-RG2 may be relatively short, and the signal attenuation may be relatively small, which may be beneficial for realizing rapid reset of the first light-emitting element and the third light-emitting element corresponding to the first pixel circuit P1 and the third pixel circuit P3, thereby being beneficial for quickly clearing the residual charge and preparing for the display of next frame.

Moreover, when the first sub-transistor T7-G1 is electrically connected to the first end of adjacent first reset transistor T7-R through the connection portion B0, the first sub-transistor T7-G1 and adjacent first reset transistor T7-R may be electrically connected to the second sub-reference voltage line Vref2-RG2 only by a single punching process, which may be beneficial for simplifying the formation process of the display panel.

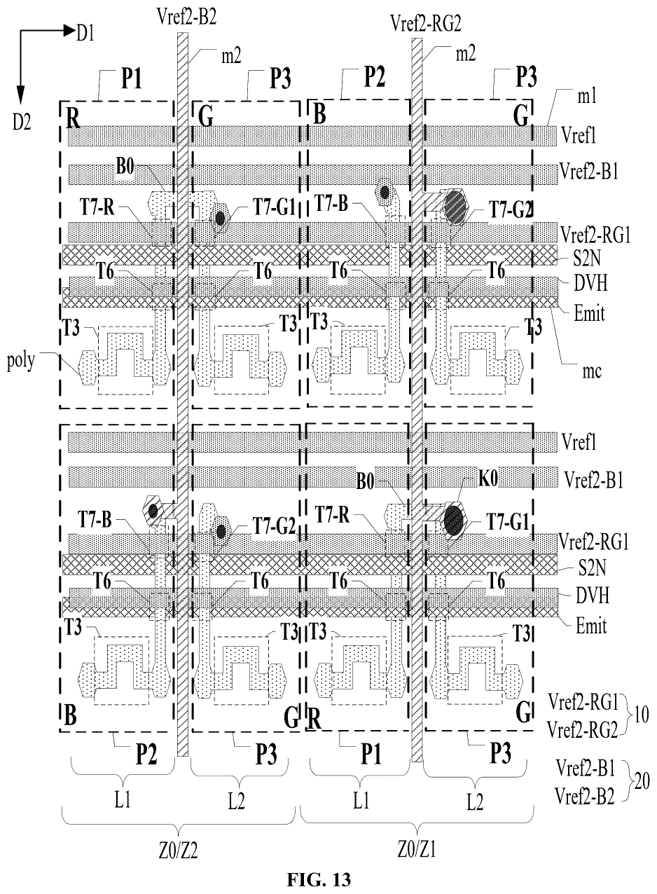

FIG. 13 illustrates a layout schematic of the circuit column group Z0 where the second sub-reference voltage line Vref2-RG2 and the fourth sub-reference voltage line Vref2-B2 are located. The difference from FIG. 12 may be that FIG. 13 further illustrates the connection between the first sub-reference voltage line Vref2-RG1 and the second sub-reference voltage line Vref2-RG2.

Referring to FIG. 13, in an optional embodiment of the present disclosure, in the circuit column group Z1 where the second sub-reference voltage line Vref2-RG2 is located, the connection portion B0 may be also electrically connected to the first sub-reference voltage line Vref2-RG1 through the connection hole K0. The first reference voltage line 10 in embodiments of the present disclosure may include the first sub-reference voltage line Vref2-RG1 extending along the first direction D1 and the second sub-reference voltage line Vref2-RG2 extending along the second direction D2. The first sub-reference voltage line Vref2-RG1 and the second sub-reference voltage line Vref2-RG2 may be in different film layers and electrically connected to each other through the connection hole. In one embodiment, when the connection portion B0 is electrically connected to the second sub-reference voltage line Vref2-RG2 extending along the second direction D2 through the connection hole K0, the connection portion B0 may be further electrically connected to the first sub-reference voltage line Vref2-RG1 extending along the first direction D1 through same connection hole K0. In such way, the connection portion B0, the first sub-reference voltage line Vref2-RG1 and the second sub-reference voltage line Vref2-RG2 may be electrically connected to each other through one connection hole K0, and there is no need to configure new connection holes separately for the connection of the first sub-reference voltage line Vref2-RG1 and the second sub-reference voltage line Vref2-RG2, which may be beneficial for simplifying the connection process of the signal line in the display panel and improving the production efficiency of the display panel.

Referring to FIGS. 12-13, in an optional embodiment of the present disclosure, in the circuit column group Z2 where the fourth sub-reference voltage line Vref2-B2 is located, the connection portion B0 may be electrically connected to the first sub-reference voltage line Vref2-RG1. Since the second sub-reference voltage line Vref2-RG2 extending along the second direction D2 is not configured in the circuit column group Z2 where the fourth sub-reference voltage line Vref2-B2 is located, the first reset transistors T7-R in the first pixel circuit P1 and the third pixel circuit P3 in the circuit column group Z0 may be connected to the first sub-reference voltage line Vref2-RG1 through the connection portion B0, and obtain the first reference voltage signal through the first sub-reference voltage line Vref2-RG1. By connecting the first sub-reference voltage line Vref2-RG1 through same connection portion B0, there is no need to respectively configure different connection portions and two punching processes for the first sub-transistor T7-G1 and the first reset transistor T7-R connected to the first sub-transistor T7-G1, which may be beneficial for simplifying the forming difficulty of the display panel and simplifying the formation process.

In above-mentioned embodiment, it describes the solution that the first sub-transistor T7-G1 and the first reset transistor T7-R adjacent to the first sub-transistor T7-G1 may be connected through the connection portion B0 and then connected to the first reference voltage line 10. In some other embodiments of the present disclosure, the first sub-transistor T7-G1 and the first reset transistor T7-R adjacent to the first sub-transistor T7-G1 may also be electrically connected to the first reference voltage line 10, respectively. For example, referring to FIG. 10, in an optional implementation manner of the present disclosure, in the circuit column group Z0, the first sub-transistor T7-G1 and the first reset transistor T7-R adjacent to the first sub-transistor T7-G1 may be electrically connected to the first reference voltage line 10, respectively. It may be understood that the first sub-transistor T7-G1 and the first reset transistor T7 adjacent to the first sub-transistor T7-G1 may be respectively connected to different points of the first reference voltage line 10. For example, referring to FIG. 10, when the first sub-transistor T7-G1 and the first reset transistor T7-R adjacent to the first sub-transistor T7-G1 are both connected to the first sub-reference voltage line Vref2-RG1 extending along the first direction D1, exemplarily, in the circuit column group Z2 where the fourth sub-reference voltage line Vref2-B2 is located, the first sub-transistor T7-G1 may be electrically connected to the first sub-reference voltage line Vref2-RG1 through a connection hole K01, and the first reset transistor T7-R adjacent to the first sub-transistor T7-G1 may be electrically connected to the first sub-reference voltage line Vref2-RG1 through another connection hole K02. Two connection holes may be connected to different positions on the first sub-reference voltage line Vref2-RG1. In such way, the electrical connection between the first reference voltage line 10 and each of the first sub-transistor T7-G1 and the first reset transistor T7-R adjacent to the first sub-transistor T7-G1 may also be achieved. Obviously, in some other embodiments of the present disclosure, the first sub-transistor T7-G1 and the first reset transistor T7 adjacent to the first sub-transistor T7-G1 may also be respectively connected to the first sub-reference voltage line Vref2-RG1 and the second sub-reference voltage line Vref2-RG2, which may be described in subsequent embodiments.

Referring to FIG. 10, in an optional embodiment of the present disclosure, in the circuit column group Z1 where the second sub-reference voltage line Vref2-RG2 is located, the first sub-transistor T7-G1 may be electrically connected to the second sub-reference voltage line Vref2-RG2, and the first reset transistor T7-R adjacent to the first sub-transistor T7-G1 may be electrically connected to the first sub-reference voltage line Vref2-RG1.

For the circuit column group Z1 where the second sub-reference voltage line Vref2-RG2 is located, the second sub-reference voltage line Vref2-RG2 may be correspondingly configured. Therefore, when the first sub-transistor T7-G1 and the first reset transistor T7-R adjacent to the first sub-transistor T7-G1 are respectively electrically connected to the first reference voltage line 10, one of the first sub-transistor T7-G1 and the first reset transistor T7-R adjacent thereto may be connected to the second sub-reference voltage line Vref2-RG2, and another one of the first sub-transistor T7-G1 and the first reset transistor T7-R adjacent thereto may be connected to the first sub-reference voltage line Vref2-RG1. In such way, the loads of the first sub-reference voltage line Vref2-RG1 and the second sub-reference voltage line Vref2-RG2 may be balanced, thereby being beneficial for improving the transmission quality of the first reference voltage signal on the first sub-reference voltage line Vref2-RG1 and the second sub-reference voltage line Vref2-RG2.

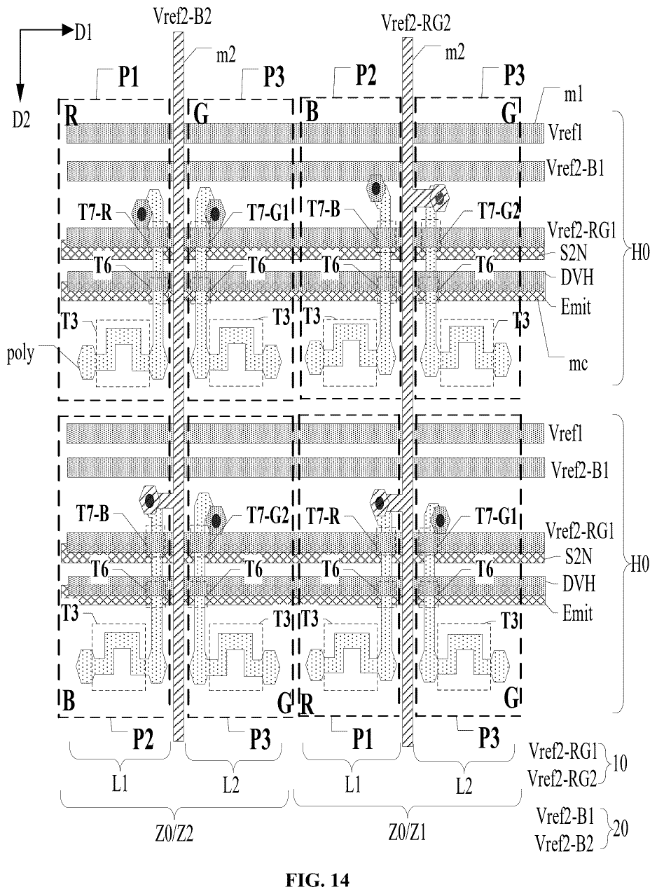

It should be noted that in one embodiment of FIG. 10, it describes that in the circuit column group Z1 where the second sub-reference voltage line Vref2-RG2 is located, the first sub-transistor T7-G1 may be electrically connected to the second sub-reference voltage line Vref2-RG2, and the first reset transistor T7-R adjacent to the first sub-transistor T7-G1 may be electrically connected to the first sub-reference voltage line Vref2-RG1. In some other embodiments of the present disclosure, also as one embodiment of FIG. 14, the first sub-transistor T7-G1 may be electrically connected to the first sub-reference voltage line Vref2-RG1, and the first reset transistor T7-R adjacent to the first sub-transistor T7-G1 may be electrically connected to the second sub-reference voltage line Vref2-RG2, which may not be limited in the present disclosure. FIG. 14 illustrates another layout schematic of the circuit column group where the second sub-reference voltage line Vref2-RG2 and the fourth sub-reference voltage line Vref2-B2 are located.

Referring to FIGS. 13-14, in an optional embodiment of the present disclosure, in the circuit column group Z1 where the second sub-reference voltage line Vref2-RG2 is located, the second sub-transistor T7-G2 may be electrically connected to the second sub-reference voltage line Vref2-RG2, and the first reset transistor T7-B adjacent to the second sub-transistor T7-G2 may be electrically connected to the third sub-reference voltage line Vref2-B1.

In one embodiment, the second sub-transistor T7-G2 may be the first reset transistor T7 in the third pixel circuit P3 corresponding to the third light-emitting element D03 (for example, the green light-emitting element); and the second sub-transistor T7-G2 may be adjacent to the first reset transistor T7-B in the second pixel circuit P2 corresponding to the second light-emitting element D02 (for example, the blue light-emitting element). For the circuit column group Z1 where the second sub-reference voltage line Vref2-RG2 is located, the second sub-reference voltage line Vref2-RG2 extending along the second direction D2 may be configured. Therefore, the second sub-transistor T7-G2 may be electrically connected to the second sub-reference voltage line Vref2-RG2 to achieve rapid resetting of the third light-emitting element. Furthermore, since the fourth sub-reference voltage line Vref2-B2 extending along the second direction D2 is not configured in the circuit column group Z0, the first reset transistor T7-B adjacent to the second sub-transistor T7-G2 may be electrically connected to the third sub-reference voltage line Vref2-B1 extending along the first direction D1, and obtain the second reference voltage signal through the third sub-reference voltage line Vref2-B1. The manner of connecting the first reset transistor T7 to nearby third sub-reference voltage line Vref2-B1 may be beneficial for simplifying overall wiring complexity of the display panel.

Referring to FIGS. 13-14, in an optional embodiment of the present disclosure, in the circuit column group Z2 where the fourth sub-reference voltage line Vref2-B2 is located, the second sub-transistor T7-G2 may be electrically connected to the first sub-reference voltage line Vref2-RG1, and the first reset transistor T7-B adjacent to the second sub-transistor T7-G2 may be electrically connected to the fourth sub-reference voltage line Vref2-B2.

In one embodiment, the second sub-transistor T7-G2 may be the first reset transistor T7 in the third pixel circuit P3 corresponding to the third light-emitting element (e.g., the green light-emitting element); and the second sub-transistor T7-G2 may be adjacent to the first reset transistor T7-B in the second pixel circuit P2 corresponding to the second light-emitting element (e.g., the blue light-emitting element). For the circuit column group Z0 where the fourth sub-reference voltage line Vref2-B2 is located, the second sub-reference voltage line Vref2-RG2 extending along the second direction D2 may be not configured. Therefore, the second sub-transistor T7-G2 may be electrically connected to the first sub-reference voltage line Vref2-RG1 extending along the first direction D1 and obtain the first reference voltage signal through the first sub-reference voltage line Vref2-RG1. In the circuit column group Z0 where the fourth sub-reference voltage line Vref2-B2 is located, the first reset transistor T7 adjacent to the second sub-transistor T7-G2 may be electrically connected to the fourth sub-reference voltage line Vref2-B2 extending along the second direction D2, thereby realizing faster transmission of the second reference voltage signal and faster reset of the second light-emitting element. Obviously, in some other embodiments of the present disclosure, the first reset transistor T7 adjacent to the second sub-transistor T7-G2 may be electrically connected to the third sub-reference voltage line Vref2-B1 extending along the first direction D1, and the second reference voltage signal may also be obtained through the third sub-reference voltage line Vref2-B1.

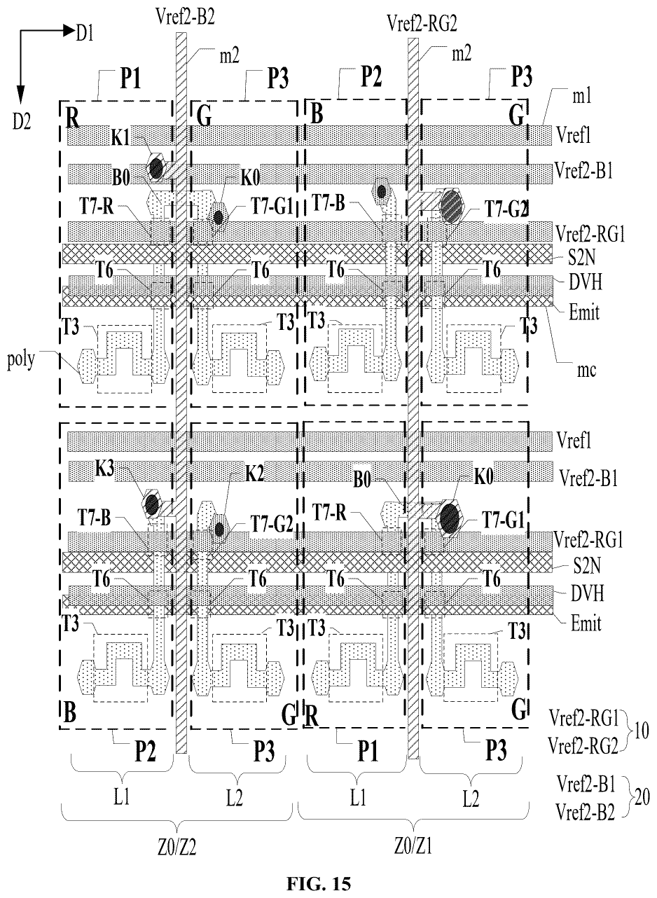

FIG. 15 illustrates another layout schematic of the circuit column group Z2 where the second sub-reference voltage line Vref2-RG2 and the fourth sub-reference voltage line Vref2-B2 are located. In one embodiment, it describes the connection between the third sub-reference voltage line Vref2-B1 and the fourth sub-reference voltage line Vref2-B2 in the circuit column group Z2 where the fourth sub-reference voltage line Vref2-B2 is located. Referring to FIG. 15, in an optional embodiment of the present disclosure, in the circuit column group Z2 where the fourth sub-reference voltage line Vref2-B2 is located, the fourth sub-reference voltage line Vref2-B2 may be electrically connected to the third sub-reference voltage line Vref2-B1 which is on the side of the fourth sub-reference voltage line Vref2-B2 away from the first sub-transistor T7-G1.

In the present disclosure, the second reference voltage line 20 may include the third sub-reference voltage line Vref2-B1 extending along the first direction D1 and the fourth sub-reference voltage line Vref2-B2 extending along the second direction D2; and the third sub-reference voltage line Vref2-B1 may be electrically connected to the fourth sub-reference voltage line Vref2-B2. Optionally, the third sub-reference voltage line Vref2-B1 and the fourth sub-reference voltage line Vref2-B2 may be respectively in different metal layers and electrically connected through a connection hole K1. In one embodiment, it describes the connection position of the third sub-reference voltage line Vref2-B1 and the fourth sub-reference voltage line Vref2-B2; and in the circuit column group Z2 where the fourth sub-reference voltage line Vref2-B2 is located, the connection position of the third sub-reference voltage line Vref2-B1 and the fourth sub-reference voltage line Vref2-B2 (for example, the position of the connection hole K1) may be on the side of the fourth sub-reference voltage line Vref2-B2 away from the first sub-transistor T7-G1. When the first sub-transistor T7-G1 and the first reset transistor T7 adjacent thereto are electrically connected through the connection portion B0, the connection position of the connection portion B0 and the first sub-reference voltage line Vref2-RG1 (for example, the position of the connection hole K0) may be configured on the side of the fourth sub-reference voltage line Vref2-B2 facing toward the first sub-transistor T7-G1. Therefore, in the circuit column group Z2 where the fourth sub-reference voltage line Vref2-B2 is located, the connection hole K0 between the first sub-transistor T7-G1 and the first reference voltage line 10, and the connection hole K1 between the third sub-reference voltage line Vref2-B1 and the fourth sub-reference voltage line Vref2-B2 may be respectively disposed on two sides of the fourth sub-reference voltage line Vref2-B2 along the first direction D1; meanwhile, the connection hole K2 between the second sub-transistor T7-G2 and the first reference voltage line 10, and the connection hole K3 between the first reset transistor T7-B adjacent to the second sub-transistor T7-G2 and the second reference voltage line 20 may also be respectively configured on two sides of the fourth sub-reference voltage line Vref2-B2 along the first direction D1, thereby being beneficial for improving overall hole layout uniformity in the display panel and improving overall display uniformity of the display panel.

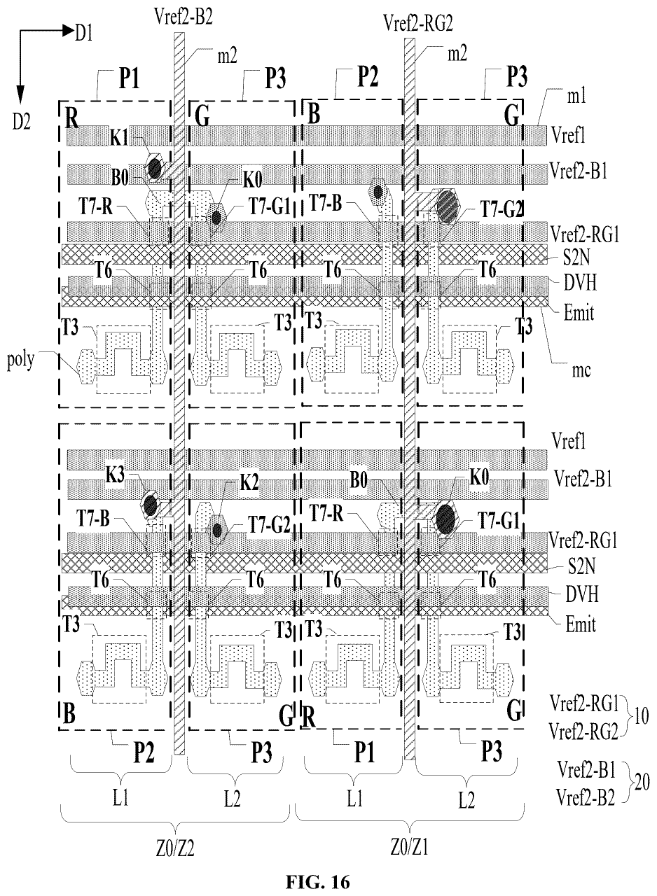

FIG. 16 illustrates a layout schematic of the circuit column group Z0 where the second sub-reference voltage line Vref2-RG2 and the fourth sub-reference voltage line Vref2-B2 are located. In one embodiment, it describes another connection between the third sub-reference voltage line Vref2-B1 and the fourth sub-reference voltage line Vref2-B2 in the circuit column group Z0 where the fourth sub-reference voltage line Vref2-B2 is located. In the circuit column group Z2 where the fourth sub-reference voltage line Vref2-B2 is located, the first reset transistor T7-B adjacent to the second sub-transistor T7-G2 may be electrically connected to the fourth sub-reference voltage line Vref2-B2 through the connection hole K3; meanwhile, the connection hole K3 may be further electrically connected to the third sub-reference voltage line Vref2-B1. In such way, the electrical connection between the third sub-reference voltage line Vref2-B1, the fourth sub-reference voltage line Vref2-B2 and the first reset transistor T7-B may be achieved through one connection hole K3, which may be beneficial for simplifying the connection process in the display panel.

Referring to FIG. 14, in an optional embodiment of the present disclosure, the display panel may include a plurality of pixel circuit rows H0 arranged along the second direction D2, and the pixel circuit row H0 may include a plurality of pixel circuits arranged along the first direction D1; the pixel circuit row H0 may be correspondingly configured with the first sub-reference voltage line Vref2-RG1 and the third sub-reference voltage line Vref2-B1; and in one row of pixel circuit rows H0, along the second direction D2, the first sub-reference voltage line Vref2-RG1 and the third sub-reference voltage line Vref2-B1 may be respectively on two sides of the first end of the first reset transistor T7. The first end of the first reset transistor T7 may be an end connected to the first reference voltage line 10 or the second reference voltage line 20. Taking the layout schematic of FIG. 14 as an example, the first end of the first reset transistor T7 may be the upper end of the first reset transistor T7 indicated by the dotted box.

In the present disclosure, the first reference voltage line 10 may include the first sub-reference voltage line Vref2-RG1 and the second sub-reference voltage line Vref2-RG2 extending along the first direction D1; and the second reference voltage line 20 may include the third sub-reference voltage line Vref2-B1 and the fourth sub-reference voltage line Vref2-B2 extending along the first direction D1. The first sub-reference voltage line Vref2-RG1 and the third sub-reference voltage line Vref2-B1 extending along the first direction D1 may be configured corresponding to the pixel circuit row H0. That is, each pixel circuit row H0 may be correspondingly configured with the first sub-reference voltage line Vref2-RG1 and the third sub-reference voltage line Vref2-B1. In such way, a part of the first reset transistors T7 (the first reset transistors T7-B corresponding to the second pixel circuits P2) in the circuit column group Z0 where the second sub-reference voltage line Vref2-RG2 is located may be conveniently connected to the third sub-reference voltage line Vref2-B1; and the first sub-transistors T7-G1 and a part of the first reset transistors T7 (the first reset transistors T7-R corresponding to the third pixel circuits P3) in the circuit column group Z0 where the fourth sub-reference voltage line Vref2-B2 is located may be conveniently connected to the first sub-reference voltage line Vref2-RG1, thereby realizing reliable reset of the anode of the light-emitting element. Meanwhile, each pixel circuit row may be correspondingly configured with the first sub-reference voltage line Vref2-RG1 and the third sub-reference voltage line Vref2-B1, which may be beneficial for realizing overall wiring uniformity of the first sub-reference voltage line Vref2-RG1 and the third sub-reference voltage line Vref2-B1 in the display panel.

In the present disclosure, the first end of the first reset transistor T7 may be an end connected to the first reference voltage line 10 or the second reference voltage line 20. In the present embodiment, it further limits that in one pixel circuit row H0, the first sub-reference voltage line Vref2-RG1 and the third sub-reference voltage line Vref2-B1 may be respectively configured on two sides of the first end of the first reset transistor T7, such that different first reset transistors T7 may be connected to nearby first sub-reference voltage line Vref2-RG1 or third sub-reference voltage line Vref2-B1, which may be beneficial for simplifying the difficulty of connecting the first reset transistor T7 with corresponding reference voltage line.

Referring to FIG. 14, in an optional embodiment of the present disclosure, the display panel may further include a plurality of drive control lines S2N/Emit; the drive control lines S2N/Emit may extend along the first direction D1 and be arranged along the second direction D2; the drive control lines S2N/Emit may be configured to provide control signals to the pixel circuits; at least a part of the drive control lines S2N/Emit may be configured in different layers from the first sub-reference voltage line Vref2-RG1 and the third sub-reference voltage line Vref2-B1; along the direction perpendicular to the plane where the display panel is located, at least one of the first sub-reference voltage line Vref2-RG1 and the third sub-reference voltage line Vref2-B1 may be overlapped with the drive control line S2N/Emit.

The drive control lines mentioned in the present disclosure may be, for example, control lines that provide control signals to the control terminals of transistors in the pixel circuits, including the control signal line S2N that provides control signals to the gate electrode of the fourth transistor T4 in one embodiment of FIG. 3, and the control signal line Emit that provides light emission control signals to the gate electrodes of the first transistor T1 and the sixth transistor T1. It should be noted that only a part of the drive control lines is illustrated in the layout schematic of the present disclosure.

In the present disclosure, the drive control line S2N/Emit may extend along the first direction D1. When the first sub-reference voltage line Vref2-RG1 and the third sub-reference voltage line Vref2-B1 extending along the first direction D1 are configured in the display panel, in order to realize reasonable arrangement of the signal lines extending along the first direction D1, the first sub-reference voltage line Vref2-RG1 and the third sub-reference voltage line Vref2-B1 may be configured in same layer; and the first sub-reference voltage line Vref2-RG1 and the third sub-reference voltage line Vref2-B1 may be configured in a different layer from at least a part of the drive control lines S2N/Emit. Meanwhile, for the drive control lines and sub-reference voltage lines configured in different layers, along the direction perpendicular to the plane where the display panel is located, at least one of the first sub-reference voltage line Vref2-RG1 and the third sub-reference voltage line Vref2-B1 may be overlapped with the drive control line S2N/Emit, which may be beneficial for reducing entire space occupied by the first sub-reference voltage line Vref2-RG1, the third sub-reference voltage line Vref2-B1 and the drive control line in the display panel along the second direction D2, which may be beneficial for achieving more compact pixel arrangement, realizing higher pixel density under same physical size, and improving the display resolution and fineness. It should be noted that in one embodiment of FIG. 14, it illustrates the solution that the second sub-reference voltage line Vref2-RG1 may be overlapped with the drive control line S2N, which may be only for illustration and not limited in the present disclosure.

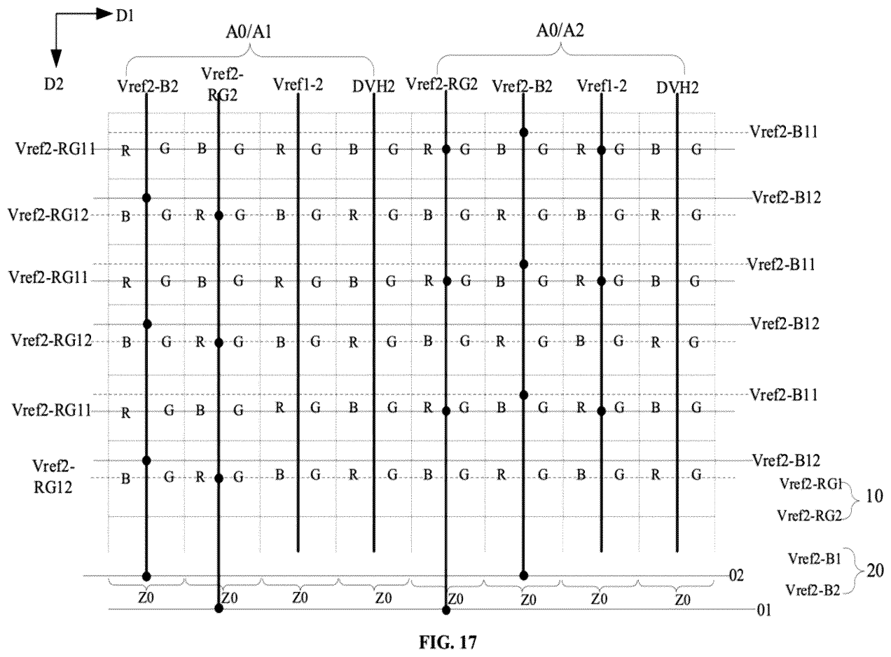

FIG. 17 illustrates a layout schematic of the first reference voltage line 10 and the second reference voltage line 20 in the display panel. Referring to FIG. 17, in an optional embodiment of the present disclosure, the first sub-reference voltage line Vref2-RG1 may include a plurality of first sub-voltage lines Vref2-RG11 and a plurality of second sub-voltage lines Vref2-RG12 which are arranged alternately along the second direction D2; at least one second sub-reference voltage line Vref2-RG2 may be electrically connected to the first sub-voltage line Vref2-RG11; and at least one second sub-reference voltage line Vref2-RG2 may be electrically connected to the second sub-voltage line Vref2-RG12.

In one embodiment, it further describes the wiring and connection manner of the first sub-reference voltage line Vref2-RG1 and the second sub-reference voltage line Vref2-RG2 in the first reference voltage line 10. For example, the first sub-reference voltage line Vref 2-RG1 extending along the first direction D1 may include the first sub-voltage line Vref2-RG11 and the second sub-voltage line Vref2-RG12 which are alternately arranged along the second direction D2. For example, the first sub-voltage line Vref2-RG11 may correspond to the pixel circuits of odd rows, and the second sub-voltage line Vref2-RG12 may correspond to the pixel circuits of even rows. Obviously, in some other embodiments of the present disclosure, the first sub-voltage line Vref2-RG11 may also correspond to the pixel circuits of even rows, and the second sub-voltage line Vref2-RG12 may correspond to the pixel circuits of odd rows. The first sub-voltage line Vref2-RG11 and the second sub-voltage line Vref2-RG12 in the first sub-reference voltage line Vref2-RG1 may be both configured to transmit the first reference voltage signal. Optionally, the first sub-voltage line Vref2-RG11 and the second sub-voltage line Vref2-RG12 in the first sub-reference voltage line Vref2-RG1 may be configured in same layer to simplify the number of film layers in the display panel. Obviously, in some other embodiments of the present disclosure, the first sub-voltage line Vref2-RG11 and the second sub-voltage line Vref2-RG12 in the first sub-reference voltage line Vref2-RG1 may also be configured in different layers, which may be not limited in the present disclosure.

In one embodiment, among the second sub-reference voltage lines Vref2-RG2 extending along the second direction D2, at least one second sub-reference voltage line Vref2-RG2 may be configured to be electrically connected to the first sub-voltage line Vref2-RG11, and form a mesh wiring structure with the first sub-voltage line Vref2-RG11; and at least one second sub-reference voltage line Vref2-RG2 may be configured to be electrically connected to the second sub-voltage line Vref2-RG12, and form another mesh wiring structure with the second sub-voltage line Vref2-RG12. Therefore, the second sub-reference voltage line Vref2-RG2, the first sub-voltage line Vref2-RG11, and the second sub-voltage line Vref2-RG12 in the first reference voltage line 10 may entirely form two mesh wiring structures, which may be beneficial for dividing the current and reducing the voltage drop caused by the line resistance, thereby ensuring that different regions of the display panel may obtain relatively stable and uniform first reference voltage signal. Moreover, the form of two mesh wiring structures may further enhance the uniformity of the voltage distribution. Such design may effectively average the voltage differences on different lines and avoid the situation where the local voltage is too high or too low. Furthermore, in two mesh wiring structures, the plurality of reference voltage lines and interconnect structures may provide redundant power supply paths. If a line fails locally or is disturbed, the current may be compensated through other paths, thereby improving the reliability and anti-interference ability of entire reference voltage network.

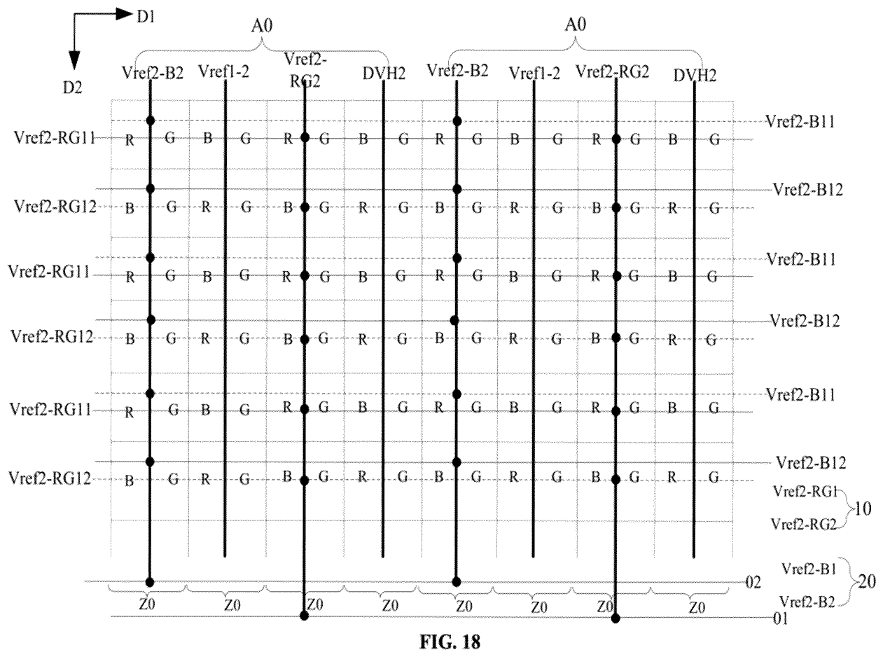

FIG. 18 illustrates another layout schematic of the first reference voltage line 10 and the second reference voltage line 20 in the display panel. Referring to FIG. 18, in an optional embodiment of the present disclosure, the first sub-reference voltage line Vref2-RG1 may include the plurality of first sub-voltage lines Vref2-RG11 and the plurality of second sub-voltage lines Vref2-RG12, which are arranged alternately along the second direction D2; and at least one second sub-reference voltage line Vref2-RG2 may be electrically connected to both the first sub-voltage line Vref2-RG11 and the second sub-voltage line Vref2-RG12.

In one embodiment, it further describes the wiring and another connection manner of the first sub-reference voltage line Vref2-RG1 and the second sub-reference voltage line Vref2-RG2 in the first reference voltage line 10. The difference from FIG. 17 may be that the second sub-reference voltage line Vref2-RG2 may be connected to a different sub-voltage line, and the similarity between FIG. 17 and FIG. 18 may be not repeated herein. In one embodiment shown in FIG. 18, at least one second sub-reference voltage line Vref2-RG2 may be electrically connected to the first sub-voltage line Vref2-RG11 and the second sub-voltage line Vref2-RG12 simultaneously. In one embodiment, each second sub-reference voltage line Vref2-RG2 may be connected to the first sub-voltage line Vref2-RG11 and the second sub-voltage line Vref2-RG12 respectively, which may be taken as an example for description. In one embodiment, the second sub-reference voltage line Vref2-RG2 extending along the second direction D2 may be configured as a connecting bridge to connect the first sub-voltage line Vref2-RG11 and the second sub-voltage line Vref2-RG12 in different horizontal directions, which means that any local voltage fluctuation may be diffused and averaged faster through the second sub-reference voltage line Vref2-RG2 extending along the second direction D2. In such way, the voltage distribution and current distribution of entire reference voltage network may be more uniform, and such effect may be more significant especially on large-size or high-resolution panels. More uniform current distribution may also reduce the current density on local lines, thereby reducing the voltage drop caused by resistance heating, avoiding the formation of local hot spots, and improving the reliability and lifetime of the display panel. Furthermore, each horizontal first sub-voltage line Vref2-RG11 and second sub-voltage line Vref2-RG12 may be connected to other horizontal sub-voltage lines through the plurality of second sub-reference voltage lines Vref2-RG2 extending along the second direction D2. If a connection point or a horizontal/vertical line fails, the current may still flow through other paths, which may ensure that the supply of reference voltage is not interrupted, thereby improving the error tolerance and reliability of entire system. In one embodiment, the connection point between the second sub-reference voltage line Vref2-RG2 and the horizontal sub-voltage line may be increased, and more interconnected lines may be equivalent to increasing the parallel resistance path, thereby reducing equivalent impedance of entire reference voltage network. Lower impedance may be beneficial for stabilizing the voltage faster and reducing transient voltage fluctuations.

Referring to FIG. 17, in an optional embodiment of the present disclosure, the third sub-reference voltage line Vref2-B1 may include the plurality of third sub-voltage lines Vref2-B11 and the plurality of fourth sub-voltage lines Vref2-B12, which are arranged alternately along the second direction D2; at least one fourth sub-reference voltage line Vref2-B2 may be electrically connected to the third sub-voltage line Vref2-B11; and at least one fourth sub-reference voltage line Vref2-B2 may be electrically connected to the fourth sub-voltage line Vref2-B12.

In one embodiment, it further describes the wiring and connection manner of the third sub-reference voltage line Vref2-B1 and the fourth sub-reference voltage line Vref2-B2 in the second reference voltage line 20. For example, the third sub-reference voltage line Vref2-B1 extending along the first direction D1 may include the third sub-voltage line Vref2-B11 and the fourth sub-voltage line Vref2-B12, which are alternately arranged along the second direction D2. For example, the third sub-voltage line Vref2-B11 may correspond to the pixel circuits of odd rows, and the fourth sub-voltage line Vref2-B12 may correspond to the pixel circuits of even rows. Obviously, in some other embodiments of the present disclosure, the third sub-voltage line Vref2-B11 may also correspond to the pixel circuits of even rows, and the fourth sub-voltage line Vref2-B12 corresponds to the pixel circuits of odd rows. The third sub-voltage line Vref2-B11 and the fourth sub-voltage line Vref2-B12 in the third sub-reference voltage line Vref2-B1 may be both configured to transmit the second reference voltage signal. Optionally, the third sub-voltage line Vref2-B11 and the fourth sub-voltage line Vref2-B12 in the third sub-reference voltage line Vref2-B1 may be arranged in same layer to simplify the number of film layers in the display panel. Obviously, in some other embodiments of the present disclosure, the third sub-voltage line Vref2-B11 and the fourth sub-voltage line Vref2-B12 in the third sub-reference voltage line Vref2-B1 may also be arranged in different layers, which may be not limited in the present disclosure.

In one embodiment, among the fourth sub-reference voltage lines Vref2-B2 extending along the second direction D2, at least one fourth sub-reference voltage line Vref2-B2 may be configured to be electrically connected to the third sub-voltage line Vref2-B11, and form a mesh wiring structure with the third sub-voltage line Vref2-B11; and at least one fourth sub-reference voltage line Vref2-B2 may be configured to be electrically connected to the fourth sub-voltage line Vref2-B12, and form another mesh wiring structure with the fourth sub-voltage line Vref2-B12. Therefore, the fourth sub-reference voltage line Vref2-B2, the third sub-voltage line Vref2-B11, and the fourth sub-voltage line Vref2-B12 in the second reference voltage line 20 may entirely form two mesh wiring structures, which may be beneficial for dividing the current and reducing the voltage drop caused by the line resistance, thereby ensuring that different regions of the display panel may obtain relatively stable and uniform second reference voltage signal. Moreover, the form of two mesh wiring structures may further enhance the uniformity of the voltage distribution. Such design may effectively average the voltage differences on different lines and avoid the situation where the local voltage is too high or too low. Furthermore, in two mesh wiring structures, the plurality of reference voltage lines and interconnect structures may provide redundant power supply paths. If a line fails locally or is disturbed, the current may be compensated through other paths, thereby improving the reliability and anti-interference ability of entire reference voltage network.

Referring to FIG. 18, in an optional embodiment of the present disclosure, the third sub-reference voltage line Vref2-B1 may include the plurality of third sub-voltage lines Vref2-B11 and the plurality of fourth sub-voltage lines Vref2-B12, which are arranged alternately along the second direction D2; and at least one fourth sub-reference voltage line Vref2-B2 may be electrically connected to both the third sub-voltage line Vref2-B11 and the fourth sub-voltage line Vref2-B12.

In one embodiment, it further describes the wiring and another connection manner of the third sub-reference voltage line Vref2-B1 and the fourth sub-reference voltage line Vref2-B2 in the second reference voltage line 20. The difference from FIG. 17 may be that the fourth sub-reference voltage line Vref2-B2 may be connected to a different sub-voltage line, and the similarity between FIG. 17 and FIG. 18 may be repeated herein. In one embodiment shown in FIG. 18, at least one fourth sub-reference voltage line Vref2-B2 may be electrically connected to the third sub-voltage line Vref2-B11 and the fourth sub-voltage line Vref2-B12 simultaneously. In one embodiment, each fourth sub-reference voltage line Vref2-B2 may be connected to the third sub-voltage line Vref2-B11 and the fourth sub-voltage line Vref2-B12 respectively, which may be taken as an example for description. In one embodiment, the fourth sub-reference voltage line Vref2-B2 extending along the second direction D2 may be configured as a connecting bridge to connect the third sub-voltage line Vref2-B11 and the fourth sub-voltage line Vref2-B12 in different transverse directions, which means that any local voltage fluctuation may be diffused and averaged to the line more quickly through the fourth sub-reference voltage line Vref2-B2 extending along the second direction D2. In such way, the voltage distribution and current distribution of entire reference voltage network may be more uniform, and such effect may be more significant especially on large-size or high-resolution panels. More uniform current distribution may also reduce the current density on local lines, thereby reducing the voltage drop caused by resistance heating, avoiding the formation of local hot spots, and improving the reliability and lifetime of the display panel. Furthermore, each horizontal third sub-voltage line Vref2-B11 and fourth third sub-voltage line Vref2-B12 may be connected to other horizontal sub-voltage lines through the plurality of fourth sub-reference voltage lines Vref2-B2 extending along the second direction D2. If a connection point or a horizontal/vertical line fails, the current may still flow through other paths, which may ensure that the supply of the reference voltage may not be interrupted, thereby improving the error tolerance and reliability of entire system. In one embodiment, the connection point between the fourth sub-reference voltage line Vref2-B2 and the horizontal sub-voltage line may be increased, and more interconnected lines may be equivalent to increasing the parallel resistance path, thereby reducing equivalent impedance of entire reference voltage network. Lower impedance may be beneficial for stabilizing the voltage faster and reducing transient voltage fluctuations.

In one embodiment shown in FIG. 17, one second sub-reference voltage line Vref2-RG2 may be connected to only one of the first sub-voltage line Vref2-RG11 and the second sub-voltage line Vref2-RG12 to form two mesh wiring structures; and one fourth sub-reference voltage line Vref2-B2 may be connected to only one of the third sub-voltage line Vref2-B11 and the fourth sub-voltage line Vref2-B12 to form two mesh wiring structures. That is, the first reference voltage line 10 may be a double mesh wiring structure, and the second reference voltage line 20 may be also a double mesh wiring structure, which may be beneficial for achieving uniform arrangement of connection holes in the display panel and improving overall display uniformity of the display panel.

In one embodiment shown in FIG. 18, one second sub-reference voltage line Vref2-RG2 may be electrically connected to the first sub-voltage line Vref2-RG11 and the second sub-voltage line Vref2-RG12 to form a mesh wiring structure; and one fourth sub-reference voltage line Vref2-B2 may be electrically connected to the third sub-voltage line Vref2-B11 and the fourth sub-voltage line Vref2-B12 to form a mesh wiring structure. That is, the first reference voltage line 10 and the second reference voltage line 20 may be both single mesh wiring structures. In such way, the uniform arrangement of the connection holes in the display panel may also be achieved, and overall display uniformity of the display panel may be improved.

In some other optional embodiments of the present disclosure, when the first reference voltage line 10 adopts a double mesh wiring structure, the second reference voltage line 20 may also be configured to a single mesh wiring structure; and when the second reference voltage line 20 adopts a double mesh wiring structure, the first reference voltage line 10 may also be configured to be a single mesh wiring structure, which may be not limited in the present disclosure.

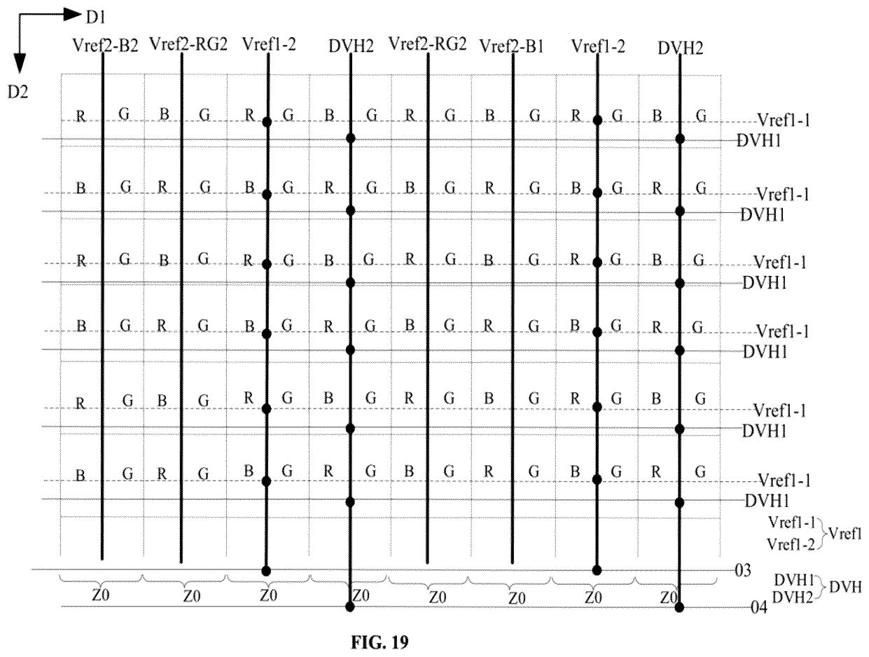

FIG. 19 illustrates a layout schematic of the second sub-reference voltage line Vref2-RG2, the fourth sub-reference voltage line Vref2-B2, the third reference voltage line Vref1 and the fourth reference voltage line DVH. It should be noted that, in order to clearly illustrate the first sub-line Vref1-1 and the second sub-line Vref1-2 in the third reference voltage line Vref1, and illustrate the third sub-line DVH1 and the fourth sub-line DVH2 in the fourth reference voltage line DVH, in one embodiment shown in FIG. 19, the first sub-reference voltage line Vref2-RG1 extending along the first direction D1 in the first reference voltage line 10 is not illustrated, and the third sub-reference voltage line Vref2-B1 extending along the first direction D1 in the second reference voltage line 20 is also not illustrated. The arrangement of the first sub-reference voltage line Vref2-RG1 and the third sub-reference voltage line Vref2-B1 may refer to FIGS. 17-18.

Referring to FIG. 19, in an optional embodiment of the present disclosure, the display panel may further include the third reference voltage line Vref1 and the fourth reference voltage line DVH. The third reference voltage line Vref1 may be configured to provide a gate reset signal to the gate electrode of the driving transistor in the pixel circuit, and the fourth reference voltage line DVH may be configured to provide a bias signal to the first electrode or the second electrode of the driving transistor in the pixel circuit. The third reference voltage line Vref1 may include the first sub-line Vref1-1 extending along the first direction D1 and the second sub-line Vref1-2 extending along the second direction D2; and the first sub-line Vref1-1 may be electrically connected to the second sub-line Vref1-2. The fourth reference voltage line DVH may include the third sub-line DVH1 extending along the first direction D1 and the fourth sub-line DVH2 extending along the second direction D2; and the third sub-line DVH1 may be electrically connected to the fourth sub-line DVH2. The second sub-reference voltage line Vref2-RG2, the fourth sub-reference voltage line Vref2-B2, the second sub-line Vref1-2 and the fourth sub-line DVH2 may correspond to different circuit column groups Z0 respectively.

In one embodiment, the first sub-lines Vref1-1 extending along the first direction D1 and the second sub-lines Vref1-2 extending along the second direction D2 in the third reference voltage line Vref1 may form a mesh wiring structure; and the third sub-lines DVH1 extending along the first direction D1 and the fourth sub-lines DVH2 extending along the second direction D2 in the fourth reference voltage line DVH may form another mesh wiring structure. The use of the mesh wiring structure may be beneficial for reducing overall impedance of the third reference voltage line Vref1 and the fourth reference voltage line DVH, dispersing the current, and reducing the voltage drop caused by the line resistance, thereby ensuring that different regions of the display panel may obtain relatively stable and uniform gate reset signals and bias signals. The first reference voltage line 10, the second reference voltage line 20, the third reference voltage line Vref1 and the fourth reference voltage line DVH may all be configured to be mesh wiring structures, which may be also beneficial for improving overall wiring uniformity and the display uniformity of the display panel.

When the first reference voltage lines 10, the second reference voltage lines 20, the third reference voltage lines Vref1 and the fourth reference voltage lines DVH are all configured to be mesh wiring structures, the first reference voltage lines 10 may include the second sub-reference voltage line Vref2-RG2 extending along the second direction D2, the second reference voltage lines 20 may include the fourth sub-reference voltage line Vref2-B2 extending along the second direction D2, the third reference voltage lines Vref1 may include the second sub-line Vref1-2 extending along the second direction D2, and the fourth reference voltage lines DVH may include the fourth sub-line DVH2 extending along the second direction D2. At this point, the second sub-reference voltage line Vref2-RG2, the fourth sub-reference voltage line Vref2-B2, the second sub-line Vref1-2 and the fourth sub-line DVH2 may respectively correspond to different circuit column groups Z0, which may be beneficial for improving the wiring uniformity of the lines extending along the second direction D2 of the display panel, thereby being beneficial for improving overall display uniformity of the display panel. Meanwhile, the signal lines transmitting different reference voltage signals may be arranged separately in different circuit column groups Z0, which may reduce the capacitive coupling and electromagnetic interference between above signal lines and reduce the risk of signal crosstalk.

Referring to FIGS. 17-18, FIG. 17 illustrates another arrangement schematic of the second sub-reference voltage line Vref2-RG2, the fourth sub-reference voltage line Vref2-B2, the third reference voltage line Vref1 and the fourth reference voltage line DVH. In an optional embodiment of the present disclosure, the display panel may include a plurality of reference line groups A0 arranged along the first direction D1; and the reference line group A0 may include four reference voltage lines, that is, the second sub-reference voltage line Vref2-RG2, the fourth sub-reference voltage line Vref2-B2, the second sub-line Vref1-2 and the fourth sub-line DVH2.

Referring to FIG. 18, in different reference line groups A0, the arrangement order of four reference voltage lines may be same. For example, the arrangement of four reference voltage lines may be embodied as the fourth sub-reference voltage line Vref2-B2, the second sub-line Vref1-2, the second sub-reference voltage line Vref2-RG2 and the fourth sub-line DVH2 which are arranged in sequence. Obviously, the arrangement herein may be only for illustration and may not limit the arrangement order of four reference voltage lines. A fixed arrangement order may be configured to arrange four reference voltage lines in different reference line groups A0, which may be beneficial for a driver chip to output and control the signals according to a time sequence, and simplifying the design of drive control logic. Obviously, the arrangement manner of four reference voltage lines in the reference line group A0 shown in FIG. 18 may be only for illustration, which may not limit the present disclosure. In some other embodiments, the arrangement manner of four reference voltage lines may also be configured as other manners.

In some other embodiments of the present disclosure, referring to FIG. 17, in adjacent reference line groups A1 and A2, the second sub-reference voltage line Vref2-RG2 and the fourth sub-reference voltage line Vref2-B2 may be interchanged, and the second sub-line Vref1-2 and the fourth sub-line DVH2 may be arranged in same position. For example, in two adjacent reference line groups A0, the arrangement of four reference voltage lines in one reference line group A1 may be embodied as the fourth sub-reference voltage line Vref2-B2, the second sub-reference voltage line Vref2-RG2, the second sub-line Vref1-2 and the fourth sub-line DVH2 which are arranged in sequence; and the arrangement of four reference voltage lines in another reference line group A2 may be embodied as the second sub-reference voltage line Vref2-RG2, the fourth sub-reference voltage line Vref2-B2, the second sub-line Vref1-2 and the fourth sub-line DVH2 which are arranged in sequence, which may be equivalent to that the arrangement positions of the fourth sub-reference voltage line Vref2-B2 and the second sub-reference voltage line Vref2-RG2 may be interchanged on the basis of previous reference line group A0, and the arrangement positions of the second sub-line Vref1-2 and the fourth sub-line DVH2 may remain unchanged. Obviously, the arrangement manner of four reference voltage lines in the reference line group A0 shown in FIG. 17 may be only for illustration, which may not limit the present disclosure. In some other embodiments, the arrangement manner of four reference voltage lines may also be configured as other manners.

For the first reference voltage signal and the second reference voltage signal provided to the light-emitting element, even slight difference may affect the initial state of the light-emitting element, thereby having a subtle effect on final brightness output and color performance. Therefore, in one embodiment, the arrangement positions of the second sub-reference voltage line Vref2-RG2 and the fourth sub-reference voltage line Vref2-B2 in the adjacent reference line group A0 may be interchanged, and regular position interchange may be configured to achieve more uniform or desired color performance on a macro scale.

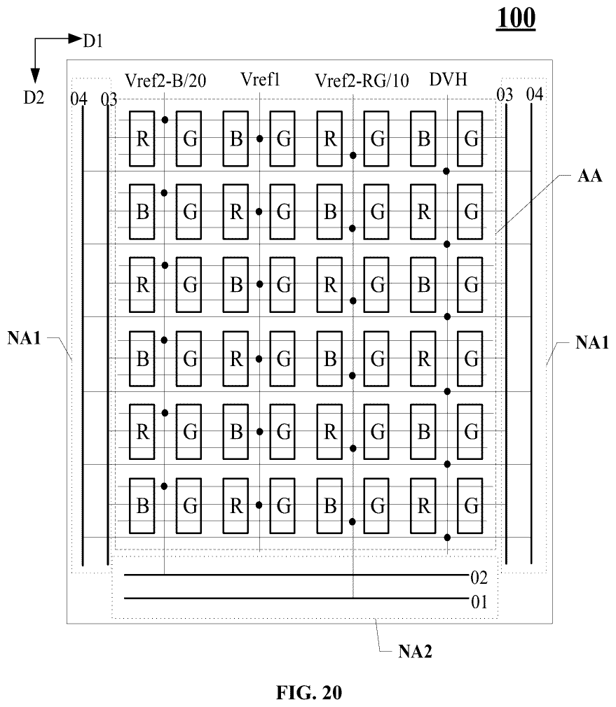

FIG. 20 illustrates a connection schematic of the reference voltage line in the display panel and the signal line in a frame region. Referring to FIG. 20, in an optional embodiment of the present disclosure, the display panel may include a display region AA, a first frame region NA1 and a second frame region NA2. The first frame regions NA1 may be on two sides of the display region AA along the first direction D1, and the second frame region NA2 may be on one side of the display region along the second direction D2. The display panel may include a first main line 01, a second main line 02, a third main line 03 and a fourth main line 04. The first main line 01 may be electrically connected to the first reference voltage line 10, the second main line 02 may be electrically connected to the second reference voltage line 20, the third main line 03 may be electrically connected to the third reference voltage line Vref1, and the fourth main line 04 may be electrically connected to the fourth reference voltage line DVH; at least two of the first main line 01, the second main line 02, the third main line 03 and the fourth main line 04 may be in the first frame region NA1, and another two of the first main line 01, the second main line 02, the third main line 03 and the fourth main line 04 may be in the second frame region NA2.

The first reference voltage line 10, the second reference voltage line 20, the third reference voltage line Vref1 and the fourth reference voltage line DVH in the display panel may all need to obtain corresponding reference voltage signals through the driver chip. Therefore, above reference voltage lines may finally need to be electrically connected to the driver chip. Optionally, the driver chip may be in the binding region of the display panel. Since the number of reference voltage lines is relatively large and the reference voltage lines are all mesh wiring structures, four reference voltage lines may be connected to the binding region through corresponding signal lines after being electrically connected to the signal lines in the frame region respectively. For example, the first main line 01 and the second main line 02 respectively connected to the first reference voltage line 10 and the second reference voltage line 20 may be configured in the second frame region NA2 of the display panel; and the third main line 03 and the fourth main line 04 respectively connected to the third reference voltage line Vref1 and the fourth reference voltage line DVH may be configured in the first frame region NA1, such that each main line may be reasonably distributed in the frame region of the display panel, which may avoiding main line aggregation in a certain frame region to cause a part of the frame to be too wide and affect the narrow frame design. Therefore, the manner of configuring different fixed main lines in the first frame region NA1 and the second frame region NA2 may be beneficial for realizing the narrow frame design of the display panel.

It should be noted that when two main lines are configured in the second frame region NA2 of the display panel and the binding region is also in the second frame region NA2, the signal transmission distance between the main line in the second frame region NA2 and the binding region may be relatively short, which may be beneficial for fast and effective transmission of corresponding signal. When two main lines are configured in the first frame region NA1 of the display panel, due to relatively large signal transmission distance between the first frame region NA1 and the binding region, two corresponding main lines may be configured in the two first frame regions NA1 at this point. For example, the third main lines 03 may be configured in the first frame region NA1 on the left and the first frame region NA1 on the right simultaneously, and both third main lines 03 may be electrically connected to the binding region. Meanwhile, the fourth main lines 04 may be configured in the first frame region NA1 on the left and the first frame region NA1 on the right simultaneously, and both fourth main lines 04 may be electrically connected to the binding region. In such way, corresponding reference voltage signal may be transmitted to the third reference voltage line Vref1 through two third main lines 03, and corresponding reference voltage signal may be transmitted to the fourth reference voltage line DVH through two fourth main lines 04, which may be also beneficial for improving the signal transmission rate from the third main line 03 and the fourth main line 04 to corresponding third reference voltage line Vref1 and fourth reference voltage line DVH.

It should also be noted that in one embodiment, it only describes the solution that the first main line 01 and the second main line 02 may be in the second frame region NA2, and the third main line 03 and the fourth main line 04 may be in the first frame region NA1. In some other embodiments of the present disclosure, the positions of the four main lines may be flexibly adjusted. For example, the first main line 01 and the second main line 02 may be configured in the first frame region NA1, and the third main line 03 and the fourth main line 04 may be configured in the second frame region NA2 or the like, which may not be limited in the present disclosure.

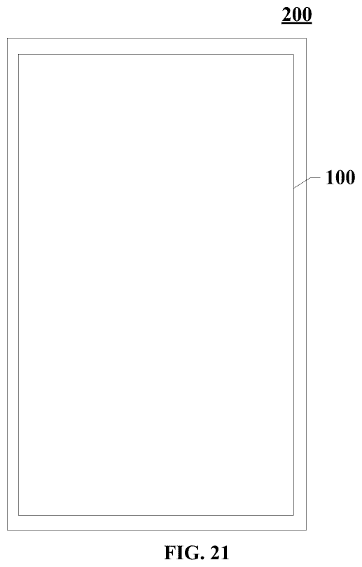

Based on same inventive concept, the present disclosure further provides a display apparatus. FIG. 21 illustrates a structural schematic of a display apparatus 200 according to various embodiments of the present disclosure. Referring to FIG. 21, the display apparatus 200 may include the display panel 100 in any of above-mentioned embodiments. The display apparatus 200 provided in embodiments of the present disclosure may be any electronic device with a display function, such as a touch screen, a mobile phone, a tablet computer, a laptop computer, an e-book or a TV. The display apparatus 200 provided in embodiments of the present disclosure may have the beneficial effects of the display panel provided in embodiments of the present disclosure, which may refer to the description of the display panel in above-mentioned embodiments and may not be described in detail in one embodiment.

It may be understood that FIG. 21 only illustrates a shape of the display apparatus 200 by taking a rectangular structure as an example. In some other embodiments of the present disclosure, the display apparatus 200 may also be embodied as a circle, an ellipse or any other feasible shape, which may be not limited in the present disclosure.

It may be seen from above-mentioned embodiments that the present disclosure may at least achieve following beneficial effects.

In the display panel and the display apparatus provided by embodiments of the present disclosure, considering that at least two light-emitting elements of different light-emitting colors have different sensitivities to temperature due to different material properties, the first reference voltage line and the second reference voltage line may be disposed respectively. The first reference voltage line and the second reference voltage line may respectively provide independent first and second reference voltage signals, which may achieve the reset of the anodes of different light-emitting elements. Therefore, the initial states of different light-emitting elements before emitting light may be more finely controlled. For example, the reference voltage corresponding to the light-emitting element, which is more sensitive to temperature, may be adjusted to ensure more stable starting points at different temperatures, thereby reducing the brightness drift caused by temperature change and finally reducing white balance deviation and reducing the problem of heating color cast. Moreover, by differentially designing the first reference voltage signal and the second reference voltage signal, more suitable initial conditions may be provided for light-emitting elements with large differences in material properties during the anode reset stage, such that subsequent driving voltage may more accurately control the brightness output of each color sub-pixel, thereby desirably maintaining the target color ratio and reducing color deviation caused by temperature.

Furthermore, for displaying at low grayscales, the driving voltage applied to the light-emitting element may be extremely close to the turn-on voltage of the light-emitting element, a slight voltage difference may result in obvious brightness changes or unevenness. Therefore, in the present disclosure, desirable reference voltage signals (such as more accurate reset voltages) may be provided for different light-emitting elements through the first reference voltage line 10 and the second reference voltage line 20, which may ensure that different light-emitting elements have predictable starting states at low grayscales. In such way, the output of different light-emitting elements at low brightness may be accurately controlled, which may ensure the light-emitting elements to accurately respond to small driving voltage changes, thereby being beneficial for reducing the problem of low grayscale color cast; and the starting states of different light-emitting elements at low brightness may be accurately controlled, which may also avoid the light leakage problem caused by signal interference between different light-emitting elements when the display panel displays monochrome pictures and due to different turn-on voltages of the light-emitting elements.

It should be noted that in the present disclosure, relational terms such as “first” and “second” may be only configured to distinguish one entity or operation from another entity or operation and may not necessarily require or imply that such actual relationship or order is between these entities or operations. Furthermore, the terms “comprise”, “include” or any other variation thereof may be intended to cover a non-exclusive inclusion. Therefore, a process, a method, an article or apparatus including a set of elements may include not only those elements, but also other elements not expressly listed, or also include elements inherent in the process, the method, the article or apparatus. Without further limitations, an element defined by the statement “include . . . ” may not exclude the presence of additional identical elements in the process, the method, the article, or apparatus including such element.

The above may be merely embodiments of the present disclosure, which may make those skilled in the art to understand or implement the present disclosure. Various modifications to embodiments of the present disclosure may be apparent to those skilled in the art. General principles defined in the present disclosure may be implemented in other embodiments without departing from the spirit or scope of the present disclosure. Therefore, the present disclosure may not be limited to embodiments described in the present disclosure but may be accorded the widest scope consistent with the principles and novel features of the present disclosure.

What is claimed is

1. A display panel, comprising:
a plurality of light-emitting elements and a plurality of pixel circuits connected to the plurality of light-emitting elements, wherein the plurality of light-emitting elements includes a first light-emitting element, a second light-emitting element and a third light-emitting element; light-emitting colors of the first light-emitting element, the second light-emitting element and the third light-emitting element are different; the plurality of pixel circuits includes a first pixel circuit, a second pixel circuit and a third pixel circuit; the first pixel circuit is electrically connected to the first light-emitting element; the second pixel circuit is electrically connected to the second light-emitting element; and the third pixel circuit is electrically connected to the third light-emitting element; and
a plurality of first reference voltage lines and a plurality of second reference voltage lines, wherein a first reference voltage line is configured to provide a first reference voltage signal to the first light-emitting element and the third light-emitting element through the first pixel circuit and the third pixel circuit, respectively; a second reference voltage line is configured to provide a second reference voltage signal to the second light-emitting element through the second pixel circuit; and a voltage value of the first reference voltage signal is different from a voltage value of the second reference voltage signal, wherein:
the plurality of first reference voltage lines includes a plurality of first sub-reference voltage lines extending along a first direction and a plurality of second sub-reference voltage lines extending along a second direction, and a first sub-reference voltage line is electrically connected to a second sub-reference voltage line; and
the plurality of second reference voltage lines includes a plurality of third sub-reference voltage lines extending along the first direction and a plurality of fourth sub-reference voltage lines extending along the second direction; a third sub-reference voltage line is electrically connected to a fourth sub-reference voltage line; and the first direction intersects the second direction.

2. The display panel according to claim 1, wherein:
turn-on voltages of the first light-emitting element and the third light-emitting element are both lower than a turn-on voltage of the second light-emitting element; and the voltage value of the first reference voltage signal is lower than the voltage value of the second reference voltage signal.

3. The display panel according to claim 2, wherein:
the first light-emitting element is one of a red light-emitting element and a blue light-emitting element, and the second light-emitting element is another one of the red light-emitting element and the blue light-emitting element; and the third light-emitting element is a green light-emitting element.

4. The display panel according to claim 1, wherein:
the display panel includes a plurality of first-type circuit columns and a plurality of second-type circuit columns, which are arranged alternately along the first direction, wherein a first-type circuit column includes a plurality of first pixel circuits and a plurality of second pixel circuits, which are arranged alternately along a second direction, and a second-type circuit column includes a plurality of third pixel circuits arranged along the second direction; and
the display panel includes a plurality of circuit column groups arranged along the first direction, wherein a circuit column group includes the first-type circuit column and the second-type circuit column which are arranged to be adjacent to each other along the first direction; and the second sub-reference voltage line and the fourth sub-reference voltage line correspond to different circuit column groups respectively.

5. The display panel according to claim 4, wherein:
in a circuit column group where the second sub-reference voltage line is located, at least one of the first pixel circuit and the third pixel circuit is electrically connected to the second sub-reference voltage line; and the second pixel circuit is electrically connected to the third sub-reference voltage line.

6. The display panel according to claim 5, wherein:
in the circuit column group where the second sub-reference voltage line is located, the first pixel circuit is electrically connected to the first sub-reference voltage line; and the third pixel circuit is electrically connected to the second sub-reference voltage line.

7. The display panel according to claim 5, wherein:
in the circuit column group where the second sub-reference voltage line is located, the first pixel circuit and the third pixel circuit are both electrically connected to the second sub-reference voltage line.

8. The display panel according to claim 4, wherein:
in a circuit column group where the fourth sub-reference voltage line is located, the second pixel circuit is electrically connected to the fourth sub-reference voltage line; and the first pixel circuit and the third pixel circuit are electrically connected to the first sub-reference voltage line.

9. The display panel according to claim 4, wherein:
a pixel circuit of the plurality of pixel circuits includes a first reset transistor, wherein a first end of the first reset transistor is connected to the first reference voltage line or the second reference voltage line, and a second end of the first reset transistor is connected to an anode of a light-emitting element; and in the second-type circuit column, first reset transistors corresponding to adjacent third pixel circuits along the second direction are respectively a first sub-transistor and a second sub-transistor; and
in a circuit column group, along the first direction, the first sub-transistor is adjacent to a first reset transistor in the first pixel circuit; the second sub-transistor is adjacent to a first reset transistor in the second pixel circuit.

10. The display panel according to claim 9, wherein:
in a circuit column group where the second sub-reference voltage line is located, a first reset transistor and the first sub-transistor or the second sub-transistor adjacent to the first reset transistor are respectively on two sides of the second sub-reference voltage line; and
in a circuit column group where the fourth sub-reference voltage line is located, a first reset transistor and the first sub-transistor or the second sub-transistor adjacent to the first reset transistor are respectively on two sides of the fourth sub-reference voltage line.

11. The display panel according to claim 9, wherein:
in the circuit column group, a first end of the first sub-transistor is electrically connected to the first end of the first reset transistor adjacent to the first sub-transistor through a connection portion.

12. The display panel according to claim 11, wherein:
in a circuit column group where the second sub-reference voltage line is located, the connection portion is electrically connected to the second sub-reference voltage line through a connection hole.

13. The display panel according to claim 12, wherein:
the connection portion is further electrically connected to the first sub-reference voltage line through the connection hole.

14. The display panel according to claim 11, wherein:
in a circuit column group where the fourth sub-reference voltage line is located, the connection portion is electrically connected to the first sub-reference voltage line.

15. The display panel according to claim 9, wherein:
in the circuit column group, the first sub-transistor and the first reset transistor adjacent to the first sub-transistor are electrically connected to the first reference voltage line, respectively.

16. The display panel according to claim 9, wherein:
in a circuit column group where the second sub-reference voltage line is located, the first sub-transistor is electrically connected to the second sub-reference voltage line; and the first reset transistor adjacent to the first sub-transistor is electrically connected to the first sub-reference voltage line.

17. The display panel according to claim 9, wherein:
in a circuit column group where the second sub-reference voltage line is located, the second sub-transistor is electrically connected to the second sub-reference voltage line; and the first reset transistor adjacent to the second sub-transistor is electrically connected to the third sub-reference voltage line.

18. The display panel according to claim 9, wherein:
in a circuit column group where the fourth sub-reference voltage line is located, the second sub-transistor is electrically connected to the first sub-reference voltage line; and the first reset transistor adjacent to the second sub-transistor is electrically connected to the fourth sub-reference voltage line.

19. The display panel according to claim 9, wherein:
in a circuit column group where the fourth sub-reference voltage line is located, on a side of the fourth sub-reference voltage line away from the first sub-transistor, the fourth sub-reference voltage line is electrically connected to the third sub-reference voltage line.

20. The display panel according to claim 9, wherein:
the display panel includes a plurality of pixel circuit rows arranged along the second direction, and a pixel circuit row includes a plurality of pixel circuits arranged along the first direction; and
a pixel circuit row is correspondingly configured with the first sub-reference voltage line and the third sub-reference voltage line; and in the pixel circuit row, along the second direction, the first sub-reference voltage line and the third sub-reference voltage line are respectively on two sides of the first end of the first reset transistor.

21. The display panel according to claim 1, wherein:
the plurality of first sub-reference voltage lines includes a plurality of first sub-voltage lines and a plurality of second sub-voltage lines, which are arranged alternately along the second direction; and
at least one second sub-reference voltage line is electrically connected to a first sub-voltage line, and at least one second sub-reference voltage line is electrically connected to a second sub-voltage line.

22. The display panel according to claim 1, wherein:
the plurality of first sub-reference voltage lines includes a plurality of first sub-voltage lines and a plurality of second sub-voltage lines, which are arranged alternately along the second direction; and
at least one second sub-reference voltage line is electrically connected to both the first sub-voltage line and the second sub-voltage line.

23. The display panel according to claim 1, wherein:
the plurality of third sub-reference voltage lines includes a plurality of third sub-voltage lines and a plurality of fourth sub-voltage lines, which are arranged alternately along the second direction; and
at least one fourth sub-reference voltage line is electrically connected to the third sub-voltage line, and at least one fourth sub-reference voltage line is electrically connected to the fourth sub-voltage line.

24. The display panel according to claim 1, wherein:
the plurality of third sub-reference voltage line includes a plurality of third sub-voltage lines and a plurality of fourth sub-voltage lines, which are arranged alternately along the second direction; and
at least one fourth sub-reference voltage line is electrically connected to both the third sub-reference voltage line and the fourth sub-reference voltage line.

25. The display panel according to claim 1, further including:
a plurality of drive control lines extending along the first direction and arranged along the second direction, wherein the plurality of drive control lines is configured to provide control signals to the plurality of pixel circuits; and
at least a part of the plurality of drive control lines is arranged in a different layer from the first sub-reference voltage line and the third sub-reference voltage line; and along a direction perpendicular to a plane of the display panel, at least one of the first sub-reference voltage line and the third sub-reference voltage line is overlapped with a drive control line.

26. The display panel according to claim 1, further including:
a plurality of third reference voltage lines and a plurality of fourth reference voltage lines, wherein:
a third reference voltage line is configured to provide a gate reset signal to a gate electrode of a driving transistor in a pixel circuit, and a fourth reference voltage line is configured to provide a bias signal to a first electrode or a second electrode of the driving transistor in the pixel circuit;
the plurality of third reference voltage lines includes a plurality of first sub-lines extending along the first direction and a plurality of second sub-lines extending along the second direction, and a first sub-line is electrically connected to a second sub-line; and the plurality of fourth reference voltage lines includes a plurality of third sub-lines extending along the first direction and a plurality of fourth sub-lines extending along the second direction, and a third sub-line is electrically connected to a fourth sub-line; and
the plurality of second sub-reference voltage lines, the plurality of fourth sub-reference voltage lines, the plurality of second sub-lines, and the plurality of fourth sub-lines correspond to different circuit column groups, respectively.

27. The display panel according to claim 26, wherein:
the display panel includes a plurality of reference line groups arranged along the first direction; and a reference line group includes four reference voltage lines, including the second sub-reference voltage line, the fourth sub-reference voltage line, the second sub-line and the fourth sub-line; and
in different reference line groups, an arrangement order of the four reference voltage lines is same; or in adjacent reference line groups, arrangement positions of the second sub-reference voltage line and the fourth sub-reference voltage line are interchanged, and arrangement positions of the second sub-line and the fourth sub-line are same.

28. The display panel according to claim 26, further including:
a display region, first frame regions and a second frame region, wherein the first frame regions are on two sides of the display region along the first direction, and the second frame region is on a side of the display region along the second direction;
a first main line, a second main line, a third main line and a fourth main line, wherein the first main line is electrically connected to the first reference voltage line, the second main line is electrically connected to the second reference voltage line, the third main line is electrically connected to the third reference voltage line, and the fourth main line is electrically connected to the fourth reference voltage line; and
at least two of the first main line, the second main line, the third main line and the fourth main line are in the first frame regions, and another two of the first main line, the second main line, the third main line and the fourth main line are in the second frame region.

29. A display apparatus, comprising:
a display panel, comprising:
a plurality of light-emitting elements and a plurality of pixel circuits connected to the plurality of light-emitting elements, wherein the plurality of light-emitting elements includes a first light-emitting element, a second light-emitting element and a third light-emitting element; light-emitting colors of the first light-emitting element, the second light-emitting element and the third light-emitting element are different; the plurality of pixel circuits includes a first pixel circuit, a second pixel circuit and a third pixel circuit; the first pixel circuit is electrically connected to the first light-emitting element; the second pixel circuit is electrically connected to the second light-emitting element; and the third pixel circuit is electrically connected to the third light-emitting element; and
a plurality of first reference voltage lines and a plurality of second reference voltage lines, wherein a first reference voltage line is configured to provide a first reference voltage signal to the first light-emitting element and the third light-emitting element through the first pixel circuit and the third pixel circuit, respectively; a second reference voltage line is configured to provide a second reference voltage signal to the second light-emitting element through the second pixel circuit; and a voltage value of the first reference voltage signal is different from a voltage value of the second reference voltage signal, wherein:
the plurality of first reference voltage lines includes a plurality of first sub-reference voltage lines extending along a first direction and a plurality of second sub-reference voltage lines extending along a second direction, and a first sub-reference voltage line is electrically connected to a second sub-reference voltage line; and
the plurality of second reference voltage lines includes a plurality of third sub-reference voltage lines extending along the first direction and a plurality of fourth sub-reference voltage lines extending along the second direction; a third sub-reference voltage line is electrically connected to a fourth sub-reference voltage line; and the first direction intersects the second direction.
